(19) United States
(12) Patent Application Publication
(10) Pub. No.: US 2014/0091397 A1
(43) Pub. Date: Apr. 3, 2014

(54) SEMICONDUCTOR INTEGRATED CIRCUIT DEVICE AND METHOD OF MANUFACTURING THEREOF

(71) Applicant: FUJITSU SEMICONDUCTOR LIMITED, Yokohama-shi (JP)

(72) Inventors: Taiji Ema, Inabe (JP); Kazushi Fujita, Kuwana (JP); Yasunobu Torii, Kuwana (JP); Mitsuaki Hori, Kuwana (JP)

(73) Assignee: FUJITSU SEMICONDUCTOR LIMITED, Yokohama-shi (JP)

(21) Appl. No.: 14/041,984

(22) Filed: Sep. 30, 2013

(30) Foreign Application Priority Data
Oct. 2, 2012 (JP) 2012-220299

(51) Int. Cl. H01L 27/092; H01L 21/8238

(52) U.S. Cl. CPC H01L 27/092; H01L 21/8238
USPC 257/369; 438/199

(57) ABSTRACT

It is therefore an object of the present invention to provide a method in which, in a semiconductor integrated circuit device, a plurality of transistors having wide-rangingly different I_{off} levels are embedded together in a semiconductor device including transistors each using a non-doped channel. By controlling an effective channel length, a leakage current is controlled without changing an impurity concentration distribution in a transistor including a non-doped channel layer and a screen layer provided immediately under the non-doped channel layer.

### CROSS-REFERENCE TO RELATED APPLICATION

This application is based upon and claims the benefit of priority of the prior Japanese Patent Application No. 2012-220299, filed on Oct. 2, 2012, the entire contents of which are incorporated herein by reference.

### FIELD

The present invention relates to a semiconductor integrated circuit device and a method of manufacturing thereof, and particularly to a semiconductor integrated circuit device in which transistors having different threshold voltages and different ON-currents or OFF-currents are integrated and a method of manufacturing thereof.

### BACKGROUND

In a semiconductor device, a transistor having a low threshold voltage Vₜₕ and a high level ON-current Iₒₙ (low-Vₜₕ transistor) and a transistor having a high threshold voltage Vₜₕ and a low level OFF-current I_{off} (high-Vₜₕ transistor) are embedded together in most cases. As such a semiconductor device, a Multi-Threshold CMOS is known.

To implement such a semiconductor integrated circuit device in which a high-Vₜₕ transistor and a low-Vₜₕ transistor are embedded together, such as the foregoing MT-CMOS, the channel doping concentration in the high-Vₜₕ transistor may be increased appropriately or, alternatively, the gate length of the high-Vₜₕ transistor may be increased appropriately.

The former approach has the advantage of allowing each of the low-Vₜₕ transistor and the high-Vₜₕ transistor to be implemented with a minimum gate length and allowing a reduction in circuit area. On the other hand, the latter approach has the advantage of allowing a reduction in the number of manufacturing process steps because of an amount of channel doping common to the low-Vₜₕ transistor and the high-Vₜₕ transistor, though the circuit area is increased. Selection of the former approach or the latter approach is determined by giving a higher priority to a reduction in circuit area or to a reduction in the number of manufacturing process steps. However, there are few cases where the latter approach is actually selected in a conventional transistor structure.

FIG. 41 is a schematic main-portion cross-sectional view of a semiconductor integrated circuit device in which each of the transistors is provided with the same gate length to have a controlled channel doping concentration. Over a semiconductor substrate 201, gate electrodes 203₁ and 203₂ are provided via a gate insulating film 202. On both sides of each of the gate electrodes 203₁ and 203₂, source/drain regions 204₁ and 204₂ are provided.

At this time, by varying the impurity concentration in channel doped regions 205₁ and 205₂, the threshold voltage Vₜₕ of each of the transistors is controlled. The transistor including the low-concentration channel doped region 205₁ serves as the transistor having the low threshold voltage Vₜₕ and the high level ON-current Iₒₙ. On the other hand, the transistor including the high-concentration channel doped region 205₂ serves as the transistor having the high threshold voltage Vₜₕ and the low level leakage current I_{off}.

Since such channel doping causes random dopant fluctuation (RDF) in the threshold voltage Vₜₕ in a chip, it has been proposed to form a channel region of a non-doped epitaxial layer (see A. Asenov et al., IEEE trans Electron devices, Vol. 46, No. 8, August 1999, U.S. Pat. No. 6,482,714).

FIG. 42 is a schematic cross-sectional view of a conventional transistor using a non-doped layer as a channel region. Between a semiconductor substrate 211 and a non-doped channel layer 213 having a thickness of about 20 nm to 25 nm, a high-impurity-concentration screen layer 212 is provided. Note that the reference numerals 214, 215, and 216 denote a gate insulating film, a gate electrode, and source/drain regions, respectively.

In this case, the screen layer 212 is provided for controlling the threshold voltage Vₜₕ and preventing a source-drain punchthrough. At this time, since the threshold voltage Vₜₕ is controlled with the screen layer 212 being away from a position immediately under the gate electrode 215 by the thickness of the non-doped channel layer 213, the screen layer 212 is doped to have a high concentration of about 1×10¹⁹ cm⁻³.

By providing such a non-doped channel layer, the fluctuations in the threshold voltage Vₜₕ in the chip can be reduced to allow an ultra-low-voltage operation. Note that, to compensate for systematic fluctuations in the threshold voltages Vₜₕ in individual chips, it is desirable to use ABB (adaptive body bias control).

### RELATED ART

1. Japanese Patent No. 3863267
2. U.S. Pat. No. 6,482,714
3. A. Asenov et. al., IEEE trans Electron devices, Vol. 46, No. 8, August 1999

In the case where the low-Vₜₕ high-Iₒₙ transistor and the high-Vₜₕ low-I_{off} transistor are embedded together using channel doping, even when the amount of channel doping is not so considerably increased, the high voltage Vₜₕ can be achieved. Accordingly, a junction leakage current does not present a serious problem.

However, with regard to the case where the low-Vₜₕ high-Iₒₙ transistor and the high-Vₜₕ low-I_{off} transistor each having a transistor structure using a non-doped channel layer are embedded together, there is no report on how to embed a plurality of transistors having widely different I_{off} levels in a semiconductor device.

### SUMMARY

A semiconductor integrated circuit device, comprising: a first transistor; and a second transistor having a threshold voltage higher than that of the first transistor, and a leakage current at a lower level than that of the first transistor, wherein, the first transistor includes a non-doped first channel region, and a first screen region in contact with and immediately under the first channel region, the second transistor includes a non-doped second channel region, and a second screen region in contact with and immediately under the second channel region, a first impurity concentration distribution in each of the first channel region and the first screen region is equal to a second impurity concentration distribution in each of the second channel region and the second screen region, and a first effective channel length of the first transistor is shorter than a second effective channel length of the second transistor.

From another disclosed viewpoint, a method of manufacturing a semiconductor integrated circuit device is provided which includes: forming a first well region of a first conductivity type in a semiconductor substrate, while forming a first screen layer having an impurity concentration higher than that of the first well region in a surface of the first well region; forming a non-doped layer over the semiconductor substrate; forming a first isolation region for dividing the first well region into a second well region of the first conductivity type and a third well region of the first conductivity type; forming a first gate electrode over the second well region via a gate insulating film, while forming a second gate electrode having a gate length greater than that of the first gate electrode over the third well region via a gate insulating film; introducing an impurity of a second conductivity type opposite to the first conductivity type into the second well region by using the first gate electrode as a mask to form a first source region and a first drain region; and introducing an impurity of the second conductivity type into the third well region by using the second gate electrode as a mask to form a second source region and a second drain region each having an impurity concentration lower than that of each of the first source region and the first drain region.

The semiconductor integrated circuit device and the method of manufacturing the same which are disclosed herein allow a plurality of transistors having widely different I_{off} levels to be embedded together in a semiconductor device including transistors each using a non-doped channel layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are basic configuration diagrams of a semiconductor integrated circuit device in an embodiment of the present invention;

FIG. 2 is an Iₒₙ-I_{off} graph of a typical transistor;

FIG. 3 is an Iₒₙ-I_{off} graph when a screen layer has a high impurity concentration;

FIG. 4 illustrates the result of actual measurement from an NMOS;

FIGS. 5A, 5B, and 5C are illustrative views of a Vₜₕ control method in the embodiment of the present invention;

FIG. 6 is a schematic main-portion cross-sectional view of a semiconductor integrated circuit device in which a low-Vₜₕ high-Iₒₙ transistor and a high-Vₜₕ low-I_{off} transistor are embedded together in Embodiment 1 of the present invention;

FIG. 7 is a qualitative illustrative view of the Iₒₙ-I_{off} characteristics of transistors in Embodiment 1 of the present invention;

FIGS. 8A and 8B are illustrative views of the result of actual measurement;

FIG. 9 illustrates the Iₒₙ-I_{off} characteristic curves of a conventional transistor using channel doping;

FIG. 10 is a schematic main-portion cross-sectional view of a semiconductor integrated circuit device in which a low-Vₜₕ high-Iₒₙ transistor and a high-Vₜₕ low-I_{off} transistor are embedded together in Embodiment 2 of the present invention;

FIGS. 11A and 11B are illustrative views of actual measurement;

FIG. 12 is a schematic main-portion cross-sectional view of a semiconductor integrated circuit device in which transistors having three types of I_{off} are embedded together in Embodiment 3 of the present invention;

FIG. 13 is a qualitative illustrative view of the Iₒₙ-I_{off} characteristics of the transistors in Embodiment 3 of the present invention;

FIGS. 14A and 14B are illustrative views of the result of actual measurement;

FIG. 15 is a schematic main-portion cross-sectional view of a newly added fourth transistor in Embodiment 4 of the present invention;

FIG. 16 is a qualitative illustrative view of the Iₒₙ-I_{off} characteristics of transistors in Embodiment 4 of the present invention;

FIGS. 17A and 17B are illustrative views of the result of actual measurement;

FIGS. 18A and 18B are illustrative views of Iₒₙ-I_{off} curves in each of IP macros in Embodiment 5 of the present invention;

FIG. 19 is a conceptual plan view of a semiconductor integrated circuit device in Embodiment 6 of the present invention;

FIG. 20 illustrates an example of a configuration of a part of a circuit included in a low-voltage-operation macro cell;

FIGS. 21A and 21B are illustrative views of some of process steps of manufacturing the semiconductor integrated circuit device before the manufacturing process is completed in Embodiment 6 of the present invention;

FIGS. 22C and 22D are illustrative views of some of the process steps of manufacturing the semiconductor integrated circuit device between the step of FIG. 21B and the completion of the manufacturing process in Embodiment 6 of the present invention;

FIGS. 23E and 23F are illustrative views of some of the process steps of manufacturing the semiconductor integrated circuit device between the step of FIG. 22D and the completion of the manufacturing process in Embodiment 6 of the present invention;

FIGS. 24G and 24H are illustrative views of some of the process steps of manufacturing the semiconductor integrated circuit device between the step of FIG. 23F and the completion of the manufacturing process in Embodiment 6 of the present invention;

FIGS. 25I and 25J are illustrative views of some of the process steps of manufacturing the semiconductor integrated circuit device between the step of FIG. 24H and the completion of the manufacturing process in Embodiment 6 of the present invention;

FIGS. 26K and 26L are illustrative views of some of the process steps of manufacturing the semiconductor integrated circuit device between the step of FIG. 25J and the completion of the manufacturing process in Embodiment 6 of the present invention;

FIGS. 27M and 27N are illustrative views of some of the process steps of manufacturing the semiconductor integrated circuit device between the step of FIG. 26L and the completion of the manufacturing process in Embodiment 6 of the present invention;

FIGS. 28O and 28P are illustrative views of some of the process steps of manufacturing the semiconductor integrated circuit device between the step of FIG. 27N and the completion of the manufacturing process in Embodiment 6 of the present invention;

FIGS. 29Q and 29R are illustrative views of some of the process steps of manufacturing the semiconductor integrated circuit device between the step of FIG. 28P and the completion of the manufacturing process in Embodiment 6 of the present invention;

FIG. 30S is an illustrative view of one of the process steps of manufacturing the semiconductor integrated circuit device between the step of FIG. 29R and the completion of the manufacturing process in Embodiment 6 of the present invention;

FIG. 31T is an illustrative view of one of the process steps of manufacturing the semiconductor integrated circuit device between the step of FIG. 30S and the completion of the manufacturing process in Embodiment 6 of the present invention;

FIG. 32U is an illustrative view of one of the process steps of manufacturing the semiconductor integrated circuit device between the step of FIG. 31T and the completion of the manufacturing process in Embodiment 6 of the present invention;

FIG. 33V is an illustrative view of one of the process steps of manufacturing the semiconductor integrated circuit device between the step of FIG. 32U and the completion of the manufacturing process in Embodiment 6 of the present invention;

FIGS. 34A and 34B are illustrative views of some of process steps of manufacturing a semiconductor integrated circuit device before the manufacturing process is completed in Embodiment 7 of the present invention;

FIGS. 35C and 35D are illustrative views of some of the process steps of manufacturing the semiconductor integrated circuit device between the step of FIG. 34B and the completion of the manufacturing process in Embodiment 7 of the present invention;

FIGS. 36E and 36F are illustrative views of some of the process steps of manufacturing the semiconductor integrated circuit device between the step of FIG. 35D and the completion of the manufacturing process in Embodiment 7 of the present invention;

FIG. 37G is an illustrative view of one of the process steps of manufacturing the semiconductor integrated circuit device between the step of FIG. 36F and the completion of the manufacturing process in Embodiment 7 of the present invention;

FIG. 38H is an illustrative view of one of the process steps of manufacturing the semiconductor integrated circuit device between the step of FIG. 37G and the completion of the manufacturing process in Embodiment 7 of the present invention;

FIG. 39I is an illustrative view of one of the process steps of manufacturing the semiconductor integrated circuit device between the step of FIG. 38H and the completion of the manufacturing process in Embodiment 7 of the present invention;

FIG. 40J is an illustrative view of one of the process steps of manufacturing the semiconductor integrated circuit device between the step of FIG. 39I and the completion of the manufacturing process in Embodiment 7 of the present invention;

FIG. 41 is a schematic main-portion cross sectional view of a semiconductor integrated circuit device in which each of transistors is provided with the same gate width to have a controlled channel doping concentration; and

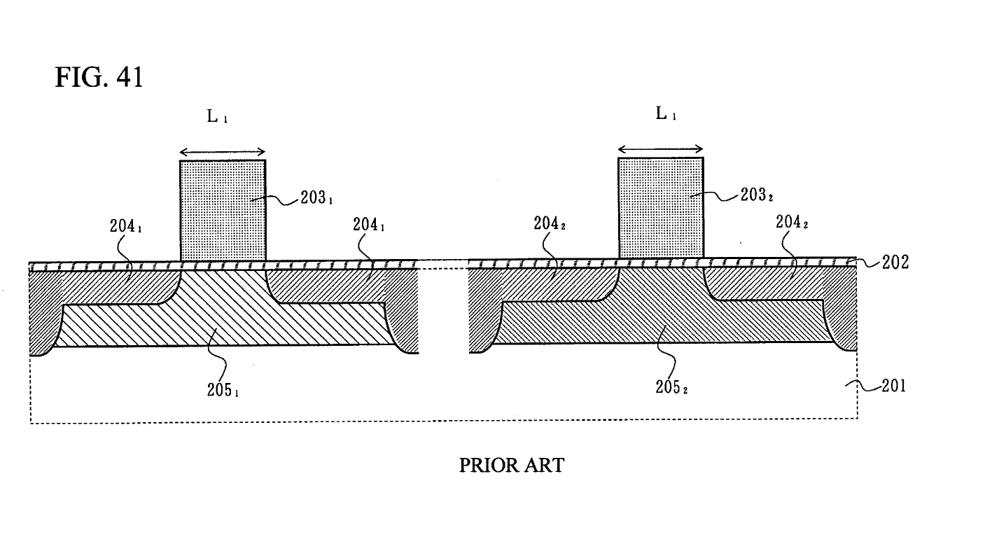

FIG. 42 is a schematic cross-sectional view of a conventional transistor using a non-doped layer as a channel region.

### DESCRIPTION OF EMBODIMENTS

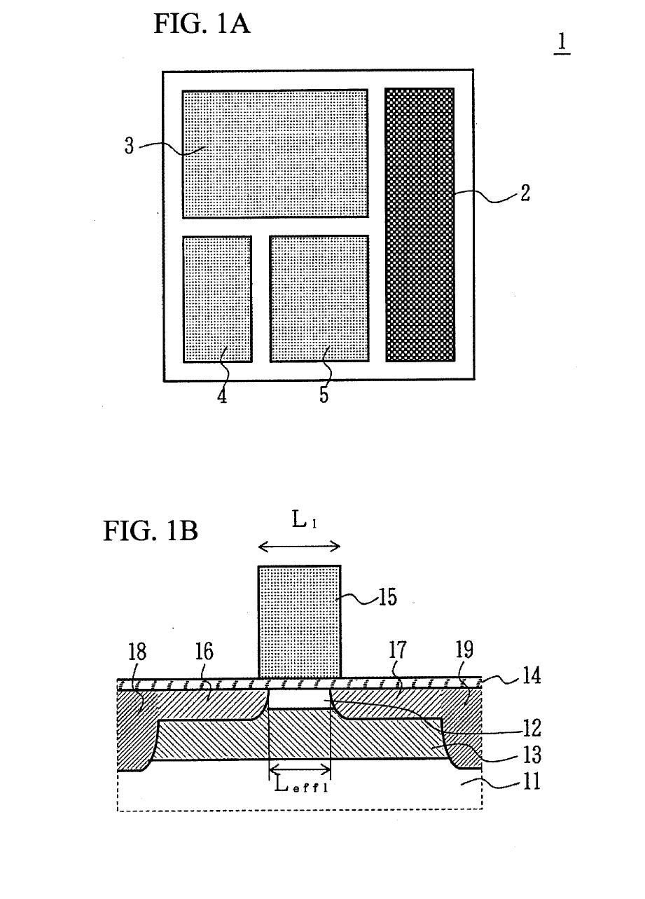

Referring now to FIGS. 1A to 5C, a semiconductor integrated circuit device in an embodiment of the present invention will be described. FIGS. 1A and 1B are basic configuration diagrams of the semiconductor integrated circuit device in the embodiment of the present invention, of which FIG. 1A is a plan view illustrating an example of an overall configuration and FIG. 1B illustrates the basic structure of a transistor.

As illustrated in FIG. 1A, a semiconductor integrated circuit device 1 includes a plurality of macro cells. The plurality of macro cells include a high-voltage-operation macro cell 2 operating at a high voltage, and low-voltage-operation macro cells 3, 4, and 5 each operating at a low voltage. Each of the low-voltage-operation macro cells 3, 4, and 5 operating at a low voltage includes a circuit obtained by combining a high-Vₜₕ transistor with a low-Vₜₕ transistor.

FIG. 1B is a schematic cross-sectional view illustrating the basic structure of a transistor formed in each transistor region. In a surface of a semiconductor substrate 11, a non-doped channel region 12 formed of a non-doped epitaxially grown layer is formed and, immediately thereunder, a screen region 13 having a high impurity concentration which controls a threshold voltage Vₜₕ and prevents a punchthrough is formed. Over the surface of the non-doped channel region 12, a gate electrode 15 is provided via a gate insulating film 14. A first source region 16 and a first drain region 17 which are shallow and have a relatively low impurity concentration are provided with the non-doped channel region 12 immediately under the gate electrode 15 being interposed therebetween. Outside the first source region 16 and the first drain region 17, a second source region 18 and a second drain region 19 which are deep and have a relatively high impurity concentration are provided.

In this case, for the gate electrode 15, polysilicon may be used, a metal such as TiN may be used, or a laminated structure of polysilicon and a metal such as TiN may also be used. The first source region 16 and the first drain region 17 result in LDD (Lightly Doped Drain) regions or extension regions, but they are not indispensable. Only the second source region 18 and the second drain region 19 may be provided appropriately.

Here, the situation leading to the present invention will be described. In the case where a low-Vₜₕ high-Iₒₙ transistor and a high-Vₜₕ low-I_{off} transistor each having a transistor structure using a non-doped channel layer are embedded together, the threshold voltage Vₜₕ is controlled using the impurity concentration in the screen layer. The present inventors have newly found that, when the threshold voltage Vₜₕ is controlled using the impurity concentration in the screen layer, compared to the case where channel doping is used, a junction leakage current presents a significantly serious problem and exerts significant influence on the formation of the high-Vₜₕ transistor.

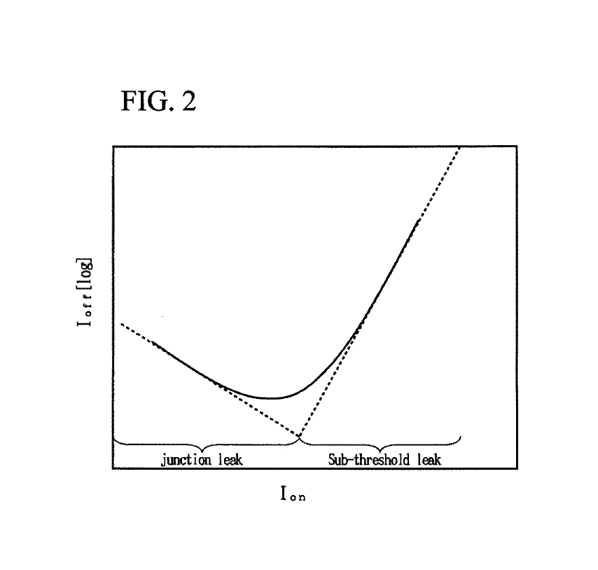

To explain the situation, a description will be given first to the Iₒₙ-I_{off} graph of a typical transistor. FIG. 2 is the Iₒₙ-I_{off} graph of a typical transistor in which the ordinate axis represents I_{off} in logarithm. As can be seen from the drawing, a leakage current I_{off} in the transistor is the sum of a subthreshold current flowing from the drain to the source and a junction leakage current flowing from the drain to the substrate.

Of the two currents, the subthreshold current is reduced by increasing Vₜₕ by means of applying a reverse voltage to the substrate or the like. By contrast, the junction leakage current is increased by increasing Vₜₕ by means of applying a reverse voltage to the substrate or the like. Since Iₒₙ is a monotonous function which decreases as Vₜₕ increases, the Iₒₙ-I_{off} graph has a minimum value.

In the case of using channel doping, even when the amount of channel doping is not so considerably increased, high Vₜₕ can be achieved. Accordingly, the junction leakage current does not present a serious problem. However, in the case of using a non-doped channel layer, Vₜₕ is controlled using the screen layer so that it is needed to further increase the originally high impurity concentration in the screen layer to a higher level.

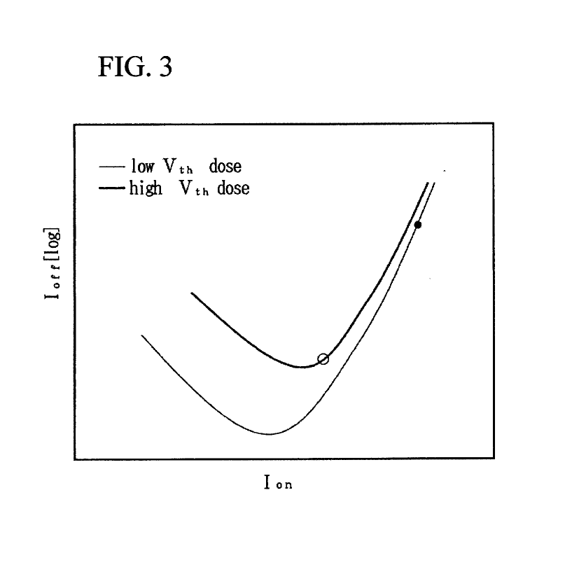

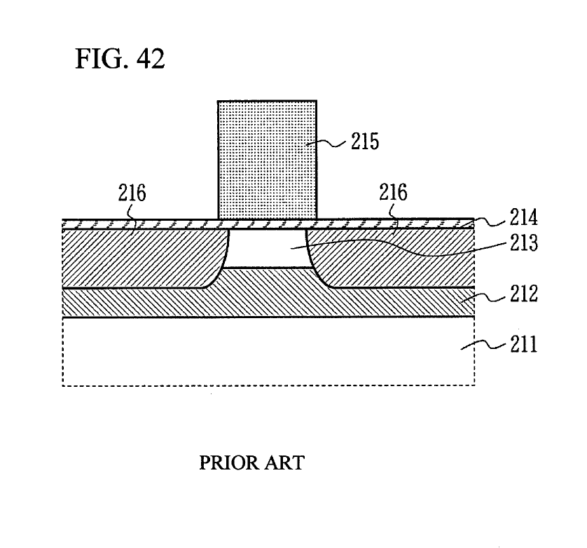

FIG. 3 is an Iₒₙ-I_{off} graph when the screen layer has a high impurity concentration. As illustrated in FIG. 42, when the screen layer has a high concentration, the junction leakage current undesirably increases to significantly increase the minimum value of the Iₒₙ-I_{off} graph. As a result, a new problem is encountered that it is difficult to reduce I_{off} to a needed level. Note that each of the circular marks in the drawing represents I_{off} at the set value of V_{bb}.

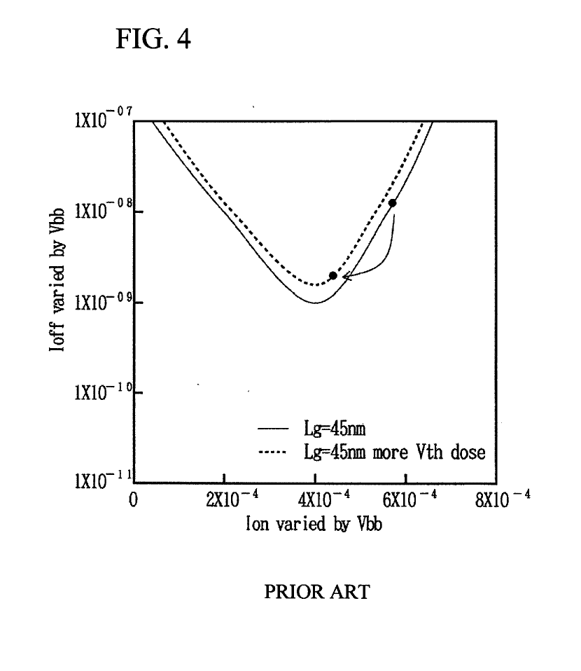

FIG. 4 illustrates the result of actual measurement from an NMOS. Here, the Iₒₙ-I_{off} curve was obtained by varying V_{bb} and thereby varying Vₜₕ. The broken line represents the case where the gate length was set to 45 nm and the dose of B when the screen layer was formed was set to 2×10¹³ cm⁻². The solid line represents the case where the gate length was set to 45 nm and the dose of B when the screen layer was formed was set to 3×10¹³ cm⁻². In either case, an effective channel length L_{eff} was about 30 nm. Note that each of the circular marks in the drawing represents I_{off} at the set value of V_{bb} when the NMOS was actually driven as a device.

As is obvious from the drawing, by increasing the dose when the screen layer was formed, the leakage current I_{off} at the set value of V_{bb} could be reduced. However, compared to the case where V_{bb} was varied in a low-dose transistor, the Iₒₙ-I_{off} ratio deteriorated and I_{off} which could be minimized undesirably had a high value of not less than 1 nA.

To solve such a problem, the threshold voltage Vₜₕ of the high-Vₜₕ low-I_{off} transistor may be controlled appropriately using V_{bb}. However, to individually and separately apply V_{bb} to the low-Vₜₕ transistor and to the high-Vₜₕ transistor, a complicated layout resulting from individual formation of the well regions or the like is needed, which is not realistic. Even when Vₜₕ is controlled using V_{bb}, the value of I_{off} which can be minimized cannot be reduced to be not than 1 nA.

The transistor using the non-doped channel layer is preferably used in combination with the ABB described above. However, at that time, during the application of a reverse body bias V_{bb} generated by charge pump circuit, the junction leakage current is further increased. The increased junction leakage current causes the need to increase the capacity of the charge pump circuit and increases the area.

It is also unknown how to embed three types of non-doped channel transistors including one having considerably low level Ioff, not two types of transistors having different threshold voltages Vₜₕ.

As described above, in the embodiment of the present invention, the threshold voltage Vₜₕ of the transistor formed in each of the transistor regions is controlled by the effective channel length L_{eff}, while providing the same impurity concentration distribution in each of the non-doped channel regions 12 and the screen regions 13. One embodiment controls the effective channel length by physical gate length. Another embodiment controls the effective channel length by source drain junction depth or both of physical gate length and source drain junction depth.

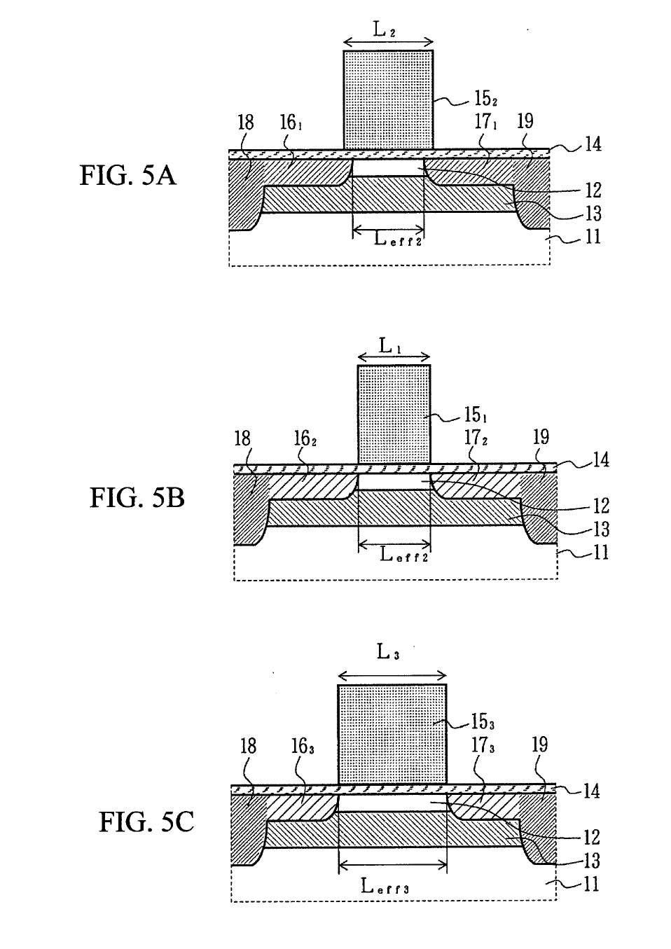

FIGS. 5A, 5B, and 5C are illustrative views of a Vₜₕ control method in the embodiment of the present invention. In FIG. 5A, the gate length of high Vth transistor is increased compared to that in the basic structure illustrated in FIG. 1B, while other conditions are kept same. Since the gate length is increased here, the effective channel length L_{eff} is naturally increased to result in a high-Vₜₕ low-leakage-current transistor.

In FIG. 5B, the impurity concentrations in the first source region 16 and the first drain region 17 of high Vth transistor are reduced compared to those in the basic structure illustrated in FIG. 1B, while other conditions including physical gate length are kept same. Since the impurity concentrations in the first source region 16 and the first drain region 17 are reduced here, the source drain junction depth including lateral direction is decreased. Accordingly, the effective channel length L_{eff} is increased to result in a high-Vₜₕ low-leakage-current transistor.

In FIG. 5C, the gate length is increased compared to that in the basic structure illustrated in FIG. 1B and the impurity concentrations in the first source region 16 and the first drain region 17 are reduced compared to those in the basic structure illustrated in FIG. 1B, while other conditions are kept same. Since the gate length is increased and the impurity concentrations in the first source region 16 and the first drain region 17 are reduced here, the combined effects achieved thereby further increase the effective channel length L_{eff}, resulting in a higher-Vₜₕ lower-leakage-current transistor.

By thus controlling the effective channel L_{eff} without changing the impurity distributions in the non-doped channel region 12 and in the screen region 13, it is possible to achieve a high threshold voltage Vₜₕ with a low level leakage current I_{off}. Note that the transistor provided in the high-voltage-operation macro cell 2 illustrated in FIG. 1A may be formed appropriately of a typical transistor having the threshold voltage Vₜₕ thereof controlled by channel doping.

### Embodiment 1

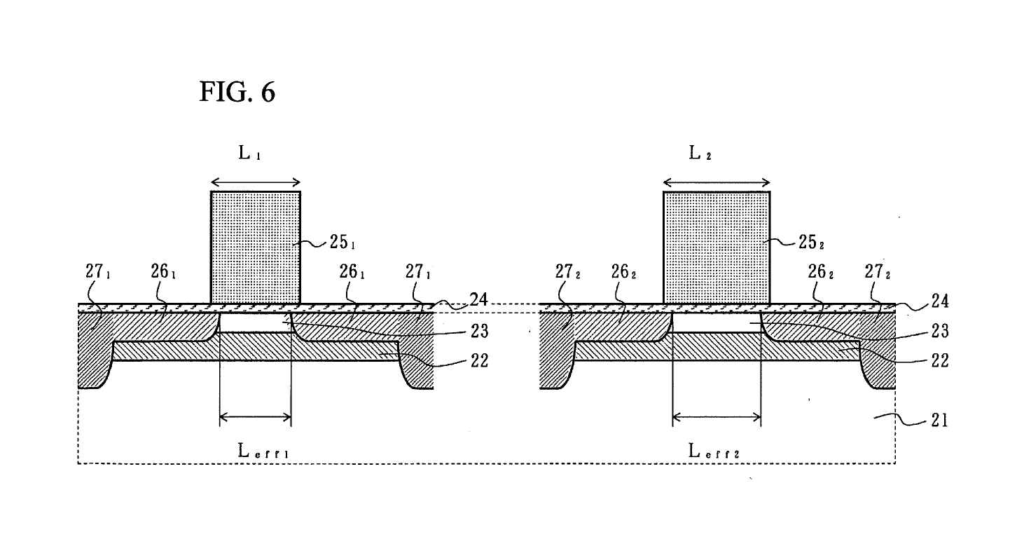

Next, referring to FIGS. 6 to 12, a semiconductor integrated circuit device in Embodiment 1 of the present invention will be described. FIG. 6 is a schematic cross-sectional view of the semiconductor integrated circuit device in which a low-Vₜₕ high-Iₒₙ transistor and a high-Vₜₕ low-I_{off} transistor are embedded together in Embodiment 1 of the present invention. The low-Vₜₕ high-Iₒₙ transistor is illustrated on the left side, while the high-Vₜₕ low-I_{off} transistor is illustrated on the right side.

As illustrated in FIG. 6, in the surface of a semiconductor substrate 21, a screen layer 22 having a concentration of 6×10¹⁸ cm⁻³ is formed, and a non-doped layer is epitaxially grown thereon to be used as a channel layer 23. The non-doped layer is intentionally not doped with an impurity, except by auto doping, to have a very low concentration of less than 1×10¹⁷ cm⁻³. The semiconductor substrate 21 is actually a well region.

Next, a gate insulating film 24 is formed, and then gate electrodes 25₁ and 25₂ are formed thereon. At this time, the gate length of the gate electrode 25₁ of the low-Vₜₕ high-Iₒₙ transistor on the left side is set to 45 nm and the gate length of the gate electrode 25₂ of the high-Vₜₕ low-I_{off} transistor on the right side is set to 55 nm.

Next, using the gate electrodes 25₁ and 25₂ as a mask, shallow ion implantation of an impurity is performed to form LDD regions 26₁ and 26₂. Then, sidewall insulating films (illustration thereof is omitted) are formed, and then deep ion implantation is performed to form source/drain regions 27₁ and 27₂, followed by heat treatment performed for activation. At this time, lateral diffusion of the implanted impurity is substantially equal in each of the left and right transistors so that the effective channel lengths L_{eff} thereof are about 30 nm and 40 nm.

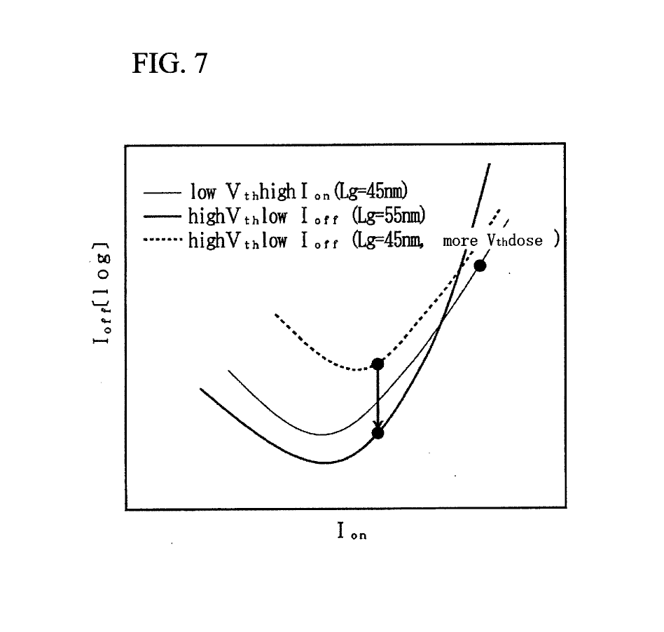

FIG. 7 is a qualitative illustrative view of the Iₒₙ-I_{off} characteristics of transistors in Embodiment 1 of the present invention. The fine solid line indicates the characteristic curve of the low-Vₜₕ high-Iₒₙ transistor, and the thick solid line indicates the characteristic curve of the high-Vₜₕ low-I_{off} transistor. Note that the broken line indicates the characteristic curve of the high-Vₜₕ low-I_{off} transistor when the dose of the screen layer is increased without changing the channel length for reference.

As indicated by the broken line in the drawing, when the dose of the screen layer is increased without changing the channel length to achieve high Vₜₕ, the junction leakage current increases so that the leakage current I_{off} does not considerably decrease. On the other hand, as indicated by the thick solid line, when the channel length is increased without changing the dose to achieve high Vₜₕ, the leakage current I_{off} significantly decreases.

The transistor structure in Embodiment 1 of the present invention is resistant to a short channel effect and primarily aims at a low-voltage operation. As a result, the gate length of the low-Vₜₕ high-Iₒₙ transistor can be set shorter than that of a transistor of a conventional type. On the other hand, the gate length of the high-Vₜₕ transistor is set similar to a conventional gate length. This can prevent increase of circuit area.

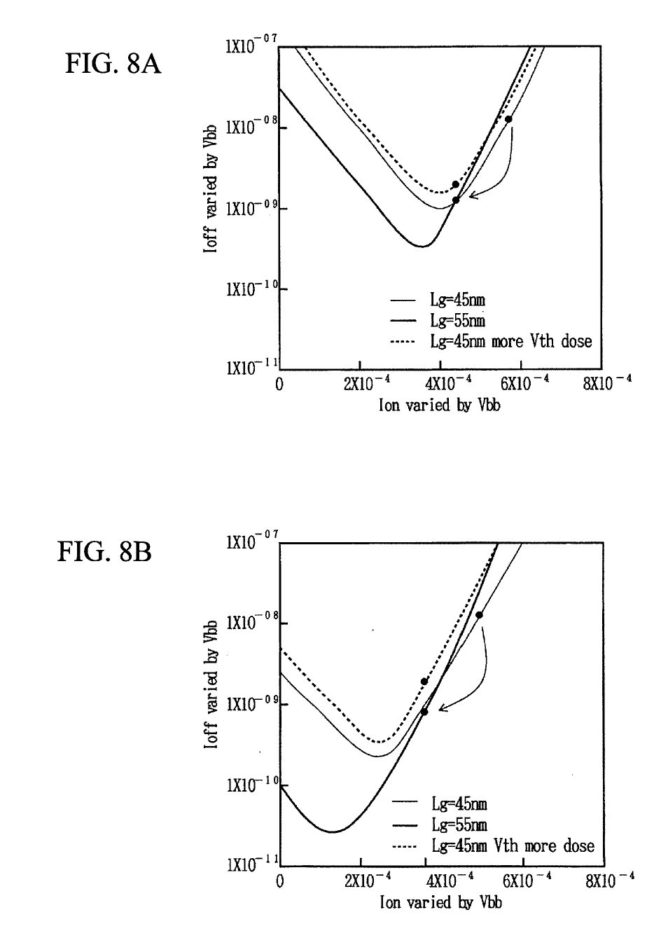

FIGS. 8A and 8B are actual measurement results, of which FIG. 8A illustrates the result of NMOS and FIG. 8B illustrates the result PMOS. In each of the drawings, the fine solid line indicates a characteristic curve when the gate length was set to 45 nm and the effective channel length was set to about 30 nm and the thick solid line indicates a characteristic curve when the gate length was set to 55 nm and the effective channel length was set to about 40 nm. Note that the broken line indicates a characteristic curve when the gate length was held at 45 nm and the impurity concentration in the screen layer was increased 1.5 times. Note that, here, the characteristic of the NMOS was examined by setting V_{dd} to 0.9 V and varying V_{bb}, while the characteristic of the PMOS was examined by setting V_{dd} to −0.9 V. Each of the circular marks in the drawings represents V_{bb} applied to a real circuit, i.e., a value at 0.3 V or −0.3 V as target V_{bb}.

As is obvious from the drawings, by achieving high Vₜₕ using the channel length without increasing the dose of the screen layer, it is possible to reduce the leakage current I_{off} at target V_{bb}, while improving the Iₒₙ-I_{off} ratio of the high-Vₜₕ low-I_{off} transistor. In addition, the value of I_{off}, which could be minimized, could also be reduced to less than 1 nA for NMOS and to a value nearly one order of magnitude less than 1 nA for PMOS.

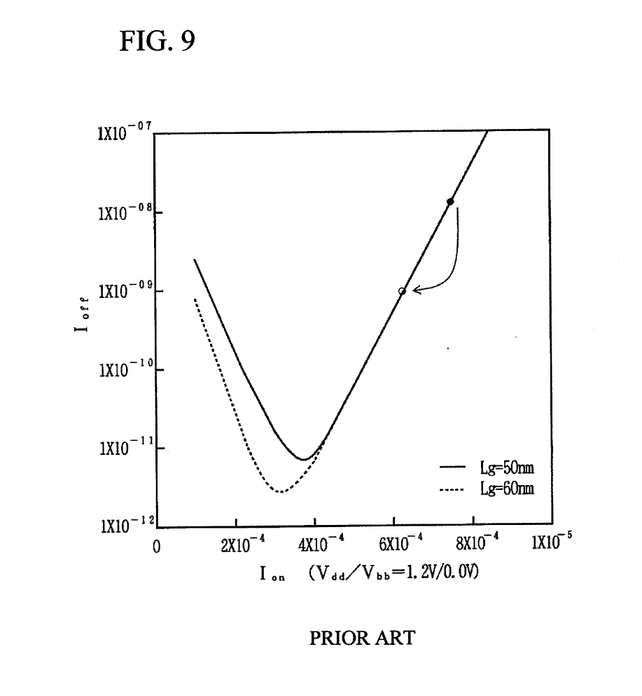

FIG. 9 illustrates the Iₒₙ-I_{off} characteristic curves of a conventional transistor using channel doping. The transistor having such a structure has lower Vbb dependence so the Iₒₙ-I_{off} characteristic curve was obtained by changing the amount of channel doping to change Vₜₕ. Note that the solid line indicates the result of measurement when the gate length was set to 50 nm and the effective channel length was set to about 35 nm, while the broken line indicates the result of measurement when the gate length was set to 60 nm and the effective channel length was set to about 45 nm. The significant improvement of Iₒₙ-I_{off} ratio observed in Embodiment 1 of the present invention was not explicitly observed in the conventional transistors.

Thus, in Embodiment 1 of the present invention, the threshold voltage Vₜₕ of the transistor is controlled using the gate length without changing the dose. It enabled to improve the Iₒₙ-I_{off} ratio and achieve low I_{off} of non-doped channel transistors, in which fluctuation of threshold voltage Vₜₕ by RDF can be significantly reduced.

### Embodiment 2

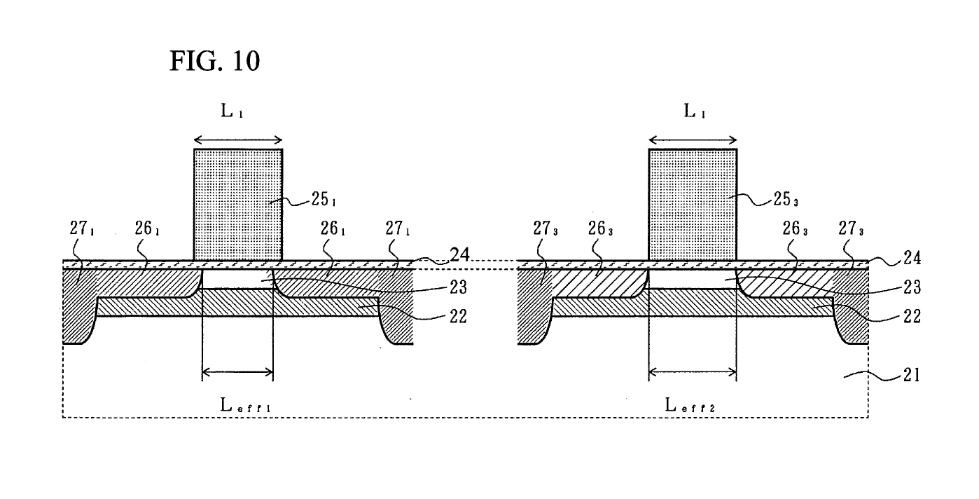

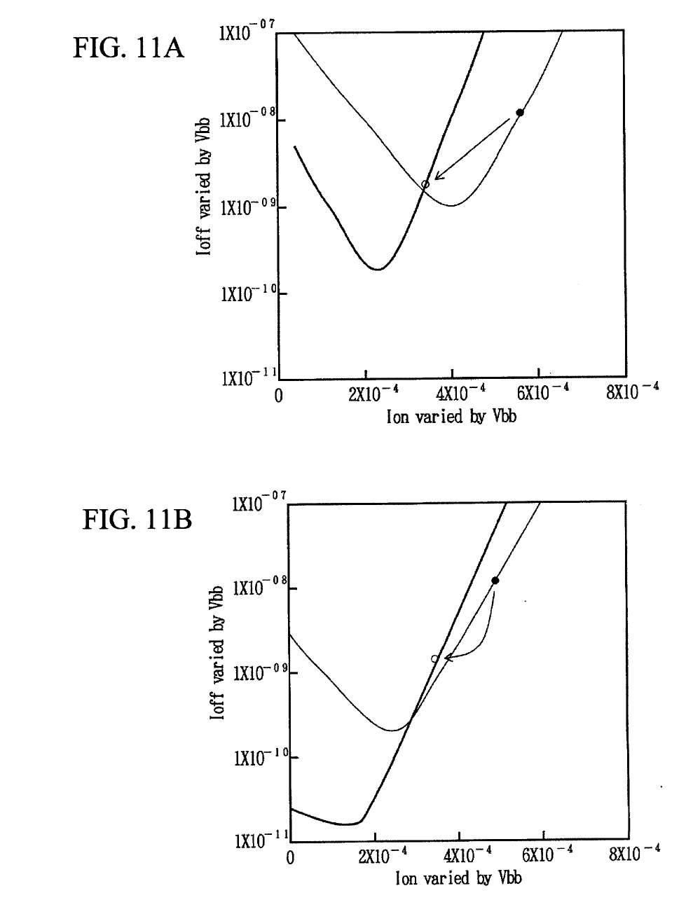

Next, referring to FIGS. 10, 11A, and 11B, a semiconductor integrated circuit device in Embodiment 2 of the present invention will be described. FIG. 10 is a schematic cross-sectional view of the semiconductor integrated circuit device in which a low-Vₜₕ high-Iₒₙ transistor and a high-Vₜₕ low-I_{off} transistor are embedded together in Embodiment 2 of the present invention. The low-Vₜₕ high-Iₒₙ transistor is illustrated on the left side, while the high-Vₜₕ low-I_{off} transistor is illustrated on the right side.

As illustrated in FIG. 10, the screen layer 22 having a concentration resulting from ion implantation of B at a dose of 2×10¹³ cm⁻² in the surface of the semiconductor substrate 21 is formed, and a non-doped layer is epitaxially grown thereon to be used as the channel layer 23. The non-doped layer is intentionally not doped with an impurity, except by auto doping, to have a very low concentration of less than 1×10¹⁷ cm⁻³. The semiconductor substrate 21 is actually a well region.

Next, the gate insulating film 24 is formed, and then gate electrodes 25₁ and 25₃ are formed thereon. At this time, the gate length of the gate electrode 25₁ of the low-Vₜₕ high-Iₒₙ transistor on the left side and the gate length of the gate electrode 25₃ of the high-Vₜₕ low-I_{off} transistor on the right side are set 45 nm.

Next, using the gate electrodes 25₁ and 25₃ as a mask, shallow ion implantation of an impurity is performed to form LDD regions 26₁ and 26₃. At this time, to form the LDD regions 26₁, As is implanted at a dose of 8×10¹⁴ cm⁻² with an acceleration energy of 1 keV and, to form the LDD regions 26₃, As is implanted at a dose of 4×10¹⁴ cm⁻² with 1 keV. Note that, for the PMOS, B is implanted at 3.6×10¹⁴ cm⁻² with 0.3 keV and at 2×10¹⁴ cm⁻² with 0.3 keV.

Next, sidewalls (illustration thereof is omitted) are formed, and then deep ion implantation is performed to form source/drain regions 27₁ and 27₃, followed by heat treatment for activation. At this time, since the impurity concentrations of the LDD regions 26₃ are lower than those of the LDD regions 26₁, the effective channel length of the transistor on the right side is consequently increased to result in high Vₜₕ.

FIGS. 11A and 11B are illustrative views of actual measurement, of which FIG. 11A illustrates measurement results of NMOS and FIG. 11B illustrates measurement results of PMOS. In each of the drawings, the fine solid line indicates the characteristic curve of the low-Vₜₕ high-Iₒₙ transistor, and the thick solid line indicates the characteristic curve of the high-Vₜₕ low-I_{off} transistor. As illustrated in the drawings, the leakage current I_{off} at target V_{bb} could be reduced by one order of magnitude. In addition, the value of minimum achievable I_{off}, could also be reduced to one order of magnitude less than 1 nA for each of the NMOS and the PMOS.

Thus, in Embodiment 2 of the present invention, Vₜₕ is controlled using the impurity concentrations of the LDD regions without changing the channel length. As a result, circuit area of non-doped transistors can be kept as same as the one of conventional transistors.

### Embodiment 3

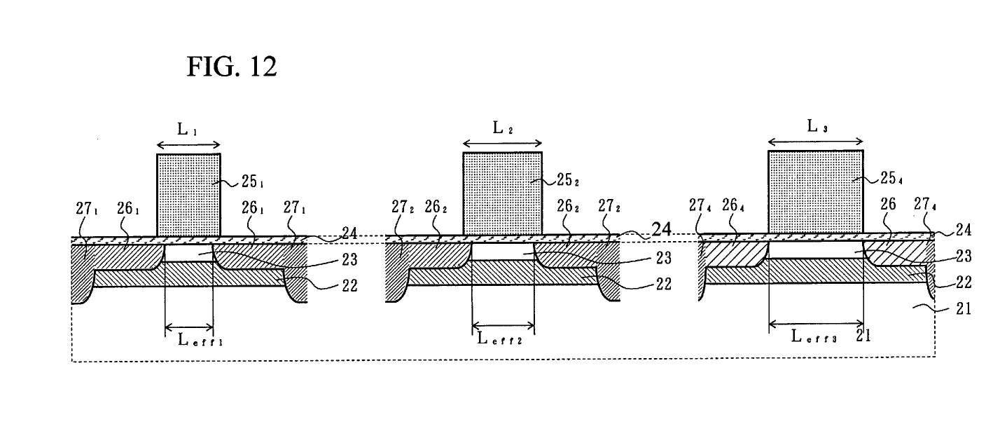

Next, referring to FIGS. 12 to 14B, a semiconductor integrated circuit device in Embodiment 3 of the present invention will be described. FIG. 12 is a schematic cross-sectional view of the semiconductor integrated circuit device in which transistors of three types of I_{off} are embedded together in Embodiment 3 of the present invention. The low-Vₜₕ high-Iₒₙ transistor is illustrated on the left side, the high-Vₜₕ low-I_{off} transistor is illustrated in the middle, and the very-high-Vₜₕ very-low I_{off} transistor is illustrated on the right side.

As illustrated in FIG. 12, the screen layer 22 having a concentration resulting from ion implantation of B at a dose of 2×10¹³ cm⁻² in the surface of the semiconductor substrate 21 is formed, and a non-doped layer is epitaxially grown thereon to be used as the channel layer 23. The non-doped layer is intentionally not doped with an impurity, except by auto doping, to have a very low concentration of not more than 1×10¹⁷ cm⁻³. The semiconductor substrate 21 is actually a well region.

Next, the gate insulating film 24 is formed, and then gate electrodes 25₁, 25₂, and 25₄ are formed thereon. At this time, the gate length of the gate electrode 25₁ of the low-Vₜₕ high-Iₒₙ transistor on the left side is set to 45 nm, and the gate length of the gate electrode 25₂ of the high-Vₜₕ low-I_{off} transistor in the middle is set to 55 nm. Also, the gate length of the gate electrode 25₄ of the very-high-Vₜₕ very-low-I_{off} transistor on the right side is set to 65 nm.

Then, using the gate electrodes 25₁, 25₂, and 25₄ as a mask, shallow ion implantation of an impurity is performed to form LDD regions 26₁, 26₂, and 26₄. At this time, to form the LDD regions 26₁ and 26₂, As is implanted at a dose of 8×10¹⁴ cm⁻² with an acceleration energy of 1 keV and, to form the LDD regions 26₄, As is implanted at a dose of 4×10¹⁴ cm⁻² with 1 keV. Note that, for the PMOS, B is implanted at 3.6×10¹⁴ cm⁻² with 0.3 keV and at 2×10¹⁴ cm⁻² with 0.3 keV.

Next, sidewalls (illustration thereof is omitted) are formed, and then deep ion implantation is performed to form source/drain regions 27₁, 27₂, and 27₄, followed by heat treatment for activation. At this time, since the impurity concentrations of the LDD regions 26₄ are lower than those of the LDD regions 26₁ and 26₂, the effective channel length of the transistor on the right side is consequently increased to result in high Vₜₕ. Note that the effective channel length of the low-Vₜₕ high-Iₒₙ transistor is about 30 nm, the effective length of the high-Vₜₕ low-I_{off} transistor is about 40 nm, and the effective length of the very-high-Vₜₕ very-low-I_{off} transistor is about 55 nm.

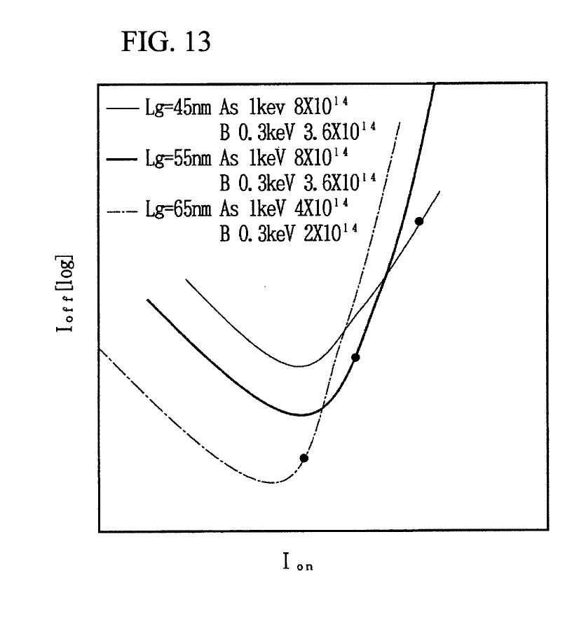

FIG. 13 is a qualitative illustrative view of the Iₒₙ-I_{off} characteristics of transistors in Embodiment 3 of the present invention. The fine solid line indicates the characteristic curve of the low-Vₜₕ high-Iₒₙ transistor, and the thick solid line indicates the characteristic curve of the high-Vₜₕ low-I_{off} transistor. On the other hand, the dot-dash line indicates the characteristic curve of the very-high-Vₜₕ very-low-I_{off} transistor. As illustrated in the drawings, when the three types of transistors having the different threshold voltages Vₜₕ are implemented, the leakage current I_{off} in the transistor having very high Vₜₕ can be significantly reduced.

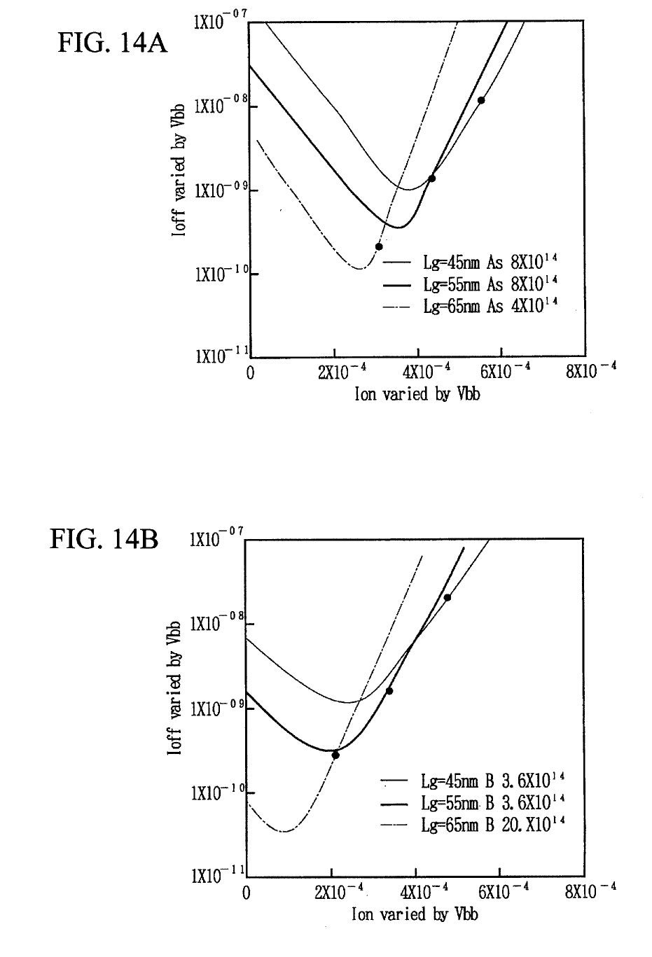

FIGS. 14A and 14B are illustrative views of actual measurement, of which FIG. 14A illustrates the measurement results of NMOS and FIG. 14B illustrates the measurement results of PMOS. In each of the drawings, the fine solid line indicates the characteristic curve of the low-Vₜₕ high-Iₒₙ transistor, the thick solid line indicates the characteristic curve of the high-Vₜₕ low-I_{off} transistor, and the dot-dash line indicates the characteristic curve of the very-high-Vₜₕ very-low-I_{off} transistor.

Thus, in Embodiment 3 of the present invention, by varying the channel length and the impurity concentrations of the LDD regions in combination, the three different threshold voltages Vₜₕ can be achieved without changing the dose.

### Embodiment 4

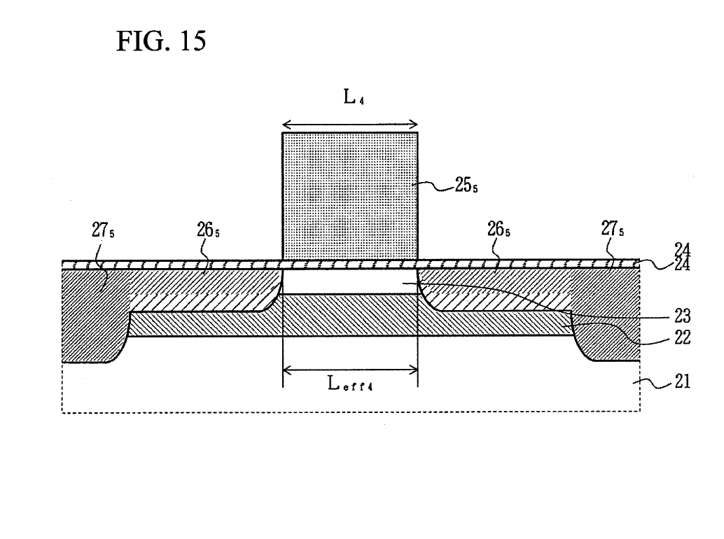

Next, referring to FIGS. 15 to 17B, a semiconductor integrated circuit device in Embodiment 4 of the present invention will be described. In Embodiment 4, in the semiconductor integrated circuit device of Embodiment 3 described above, a fourth transistor having a much lower level leakage current I_{off} is formed. FIG. 15 is a schematic cross-sectional view of the newly added fourth transistor in Embodiment 4 of the present invention. The gate length is set to 115 nm, and LDD regions 26₅ are formed by two-step ion implantation to have graded impurity concentration distributions, thereby reducing the junction leakage current and further reducing the leakage current I_{off}. Note that the effective channel length is about 100 nm.

Specifically, As is implanted at a dose of 2×10¹⁴ cm⁻² with 1 keV, and P is implanted at a dose of 2×10¹⁴ cm⁻² with 1 keV. Since P is diffused faster than As, the gradient of the impurity concentration in the vicinity of the pn junction formed between each of the LDD regions 26₅ and the screen layer is less steep and the junction leakage current is reduced. Note that the junction leakage current when B is implanted at 2×10¹⁴ cm⁻² with 0.3 keV for the PMOS is at a low level. Accordingly, the leakage current I_{off} can be sufficiently reduced using only the gate length.

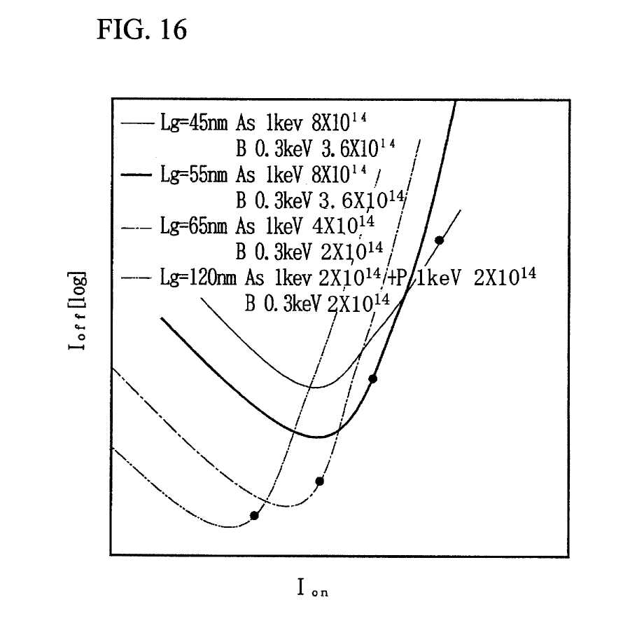

FIG. 16 is a qualitative illustrative view of the Iₒₙ-I_{off} characteristics of transistors in Embodiment 4 of the present invention. The fine solid line indicates the characteristic curve of the low-Vₜₕ high-Iₒₙ transistor, and the thick solid line indicates the characteristic curve of the high-Vₜₕ low-I_{off} transistor. On the other hand, the dot-dash line indicates the characteristic curve of the very-high-Vₜₕ very-low-I_{off} transistor, and the two-dot-dash line indicates the characteristic curve of the newly added very-high-Vₜₕ very-low-I_{off} transistor. As illustrated in the drawing, by providing the less steep impurity concentration distributions in the LDD regions, the leakage current I_{off} can be further reduced.

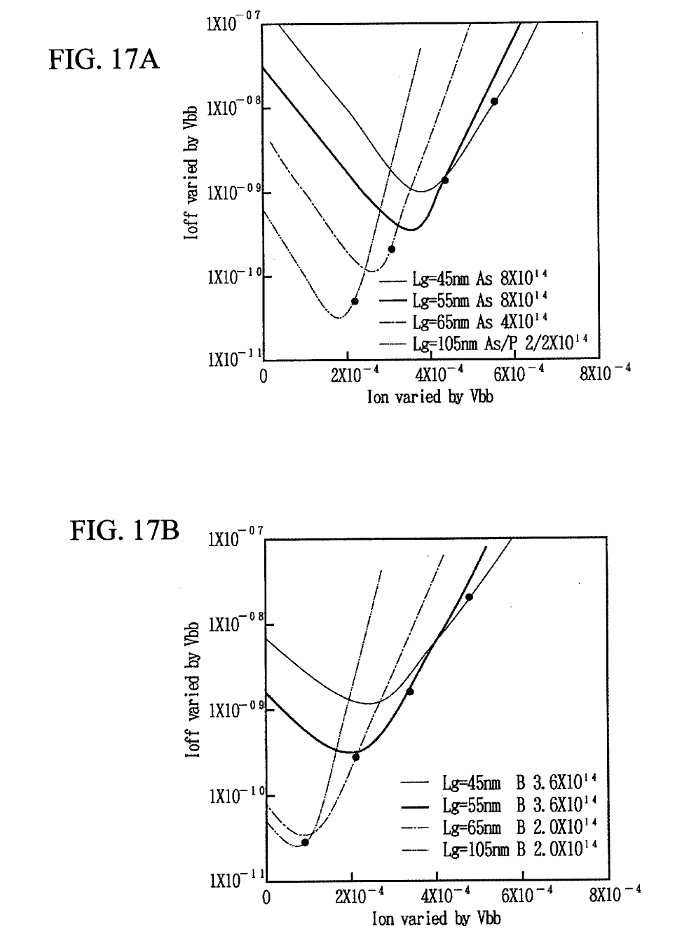

FIGS. 17A and 17B are illustrative views of actual measurement, of which FIG. 17A illustrates measurement results of NMOS and FIG. 17B illustrates measurement results of PMOS. In each of the drawings, the fine solid line indicates the characteristic curve of the low-Vₜₕ high-Iₒₙ transistor, and the thick solid line indicates the characteristic curve of the high-Vₜₕ low-I_{off} transistor. On the other hand, the dot-dash line indicates the characteristic curve of the very-high-Vₜₕ very-low-I_{off} transistor, and the two-dot-dash line indicates the characteristic curve of the newly added very-high-Vₜₕ very-low-I_{off} transistor.

Thus, in Embodiment 4 of the present invention, by varying the channel length, the impurity concentrations of the LDD regions, and distribution of the concentrations in combination, the four different threshold voltages Vₜₕ and the different leakage current I_{off} can be achieved without changing the screen dose. If, e.g., ion implantation of P at 1×10¹⁴ cm⁻² with 2 keV is applied to the NMOS and ion implantation of B at 5×10¹³ cm⁻³ with 0.6 keV is applied to the PMOS as needed, the gradient of the impurity concentration at the pn junction becomes much less steep to achieve a further reduction in leakage current I_{off}.

### Embodiment 5

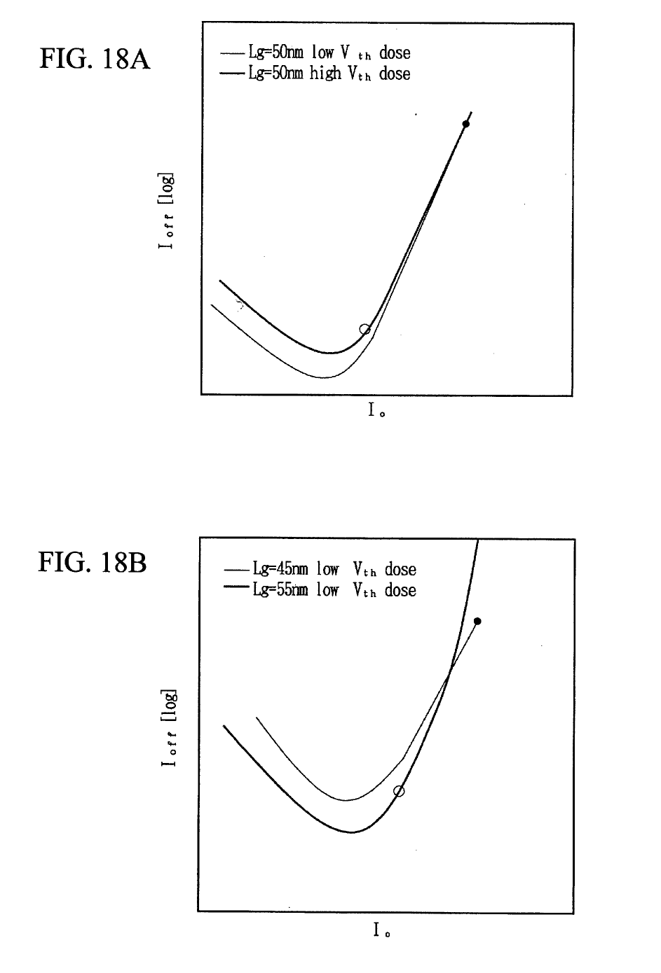

Next, referring to FIGS. 18A and 18B, a semiconductor integrated circuit device in Embodiment 5 of the present invention will be described. Embodiment 5 enables IP macros to be commonly used for conventional channel-doped transistors and any of the transistors in Embodiments 1 to 4 described above.

In each of IP macros based on the conventional channel-doped transistor, the same gate length is used and the threshold voltage Vₜₕ is controlled using the amount of channel doping. On the other hand, in each of IP macros based on the transistors in Embodiments 1 to 4 described above, the threshold voltage Vₜₕ is controlled using the gate length and the impurity concentrations of the LDD regions.

FIGS. 18A and 18B are illustrative views of Iₒₙ-I_{off} curves in each of the IP macros in Embodiment 5 of the present invention. FIG. 18A illustrates the Iₒₙ-I_{off} curve in each of the IP macros using the conventional transistors, which is illustrated here as an example in which the gate length is set to 50 nm and Vₜₕ is controlled using the amount of channel doping.

FIG. 18B illustrates the Iₒₙ-I_{off} curve in each of the IP macros using the transistors in the embodiments of the present invention, which is illustrated here as an example in which the gate length of the low-Vₜₕ high-Iₒₙ transistor is set to 45 nm and the gate length of the high-Vₜₕ low-I_{off} transistor is set to 55 nm. The foregoing configuration can be implemented by extracting data on each of the low-Vₜₕ high-Iₒₙ transistor and the high-Vₜₕ low-I_{off} transistor from the design data of the IP macro using the conventional transistor and reducing or increasing the gate length by 5 nm. The operation can be automatically performed to substantially allow the IP macros to be commonly used.

### Embodiment 6

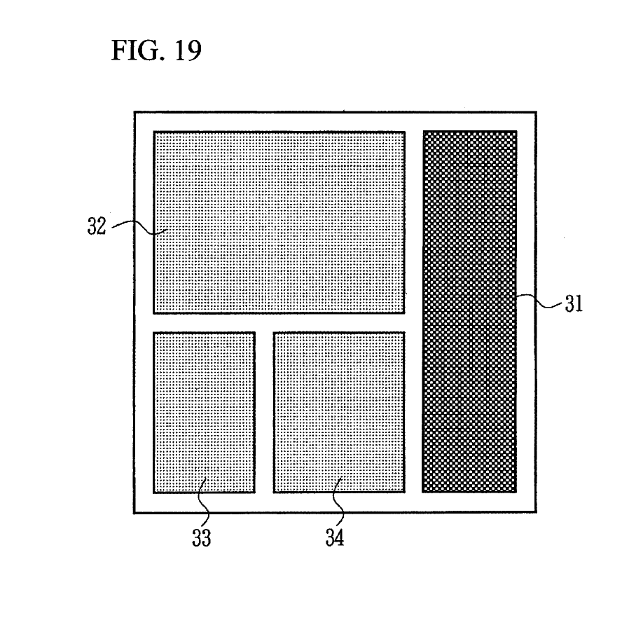

Next, referring to FIGS. 19 to 33V, a semiconductor integrated circuit device in Embodiment 6 of the present invention will be described. Note that FIGS. 19 to 33V illustrate a manufacturing method including each of the semiconductor devices in Embodiments 1 to 5.

FIG. 19 is a conceptual plan view of the semiconductor integrated circuit device in Embodiment 6 of the present invention. The semiconductor integrated circuit device includes a plurality of macro cells. The plurality of macro cells include a high-voltage-operation macro cell 31 operating at a high voltage, and low-voltage-operation macro cells 32, 33, and 34 each operating at a low voltage. Each of the low-voltage-operation macro cells 32, 33, and 34 operating at low voltages include a circuit obtained by combining a high-Vₜₕ transistor with a low-Vₜₕ transistor.

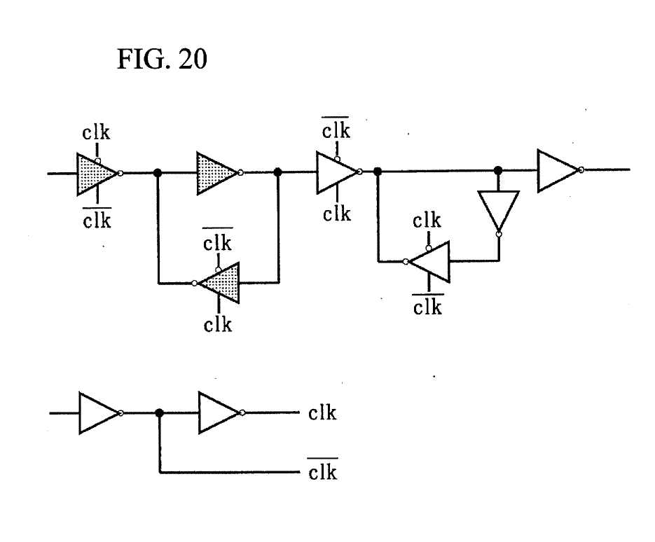

FIG. 20 illustrates an example of a configuration of a part of the circuit included in each of the low-voltage-operation macro cells. In the drawing, each of the circuits indicated by the solid dots is formed of the high-Vₜₕ transistor. In the drawing, each of the circuits indicated by the blank dots is formed of the low-Vₜₕ transistor.

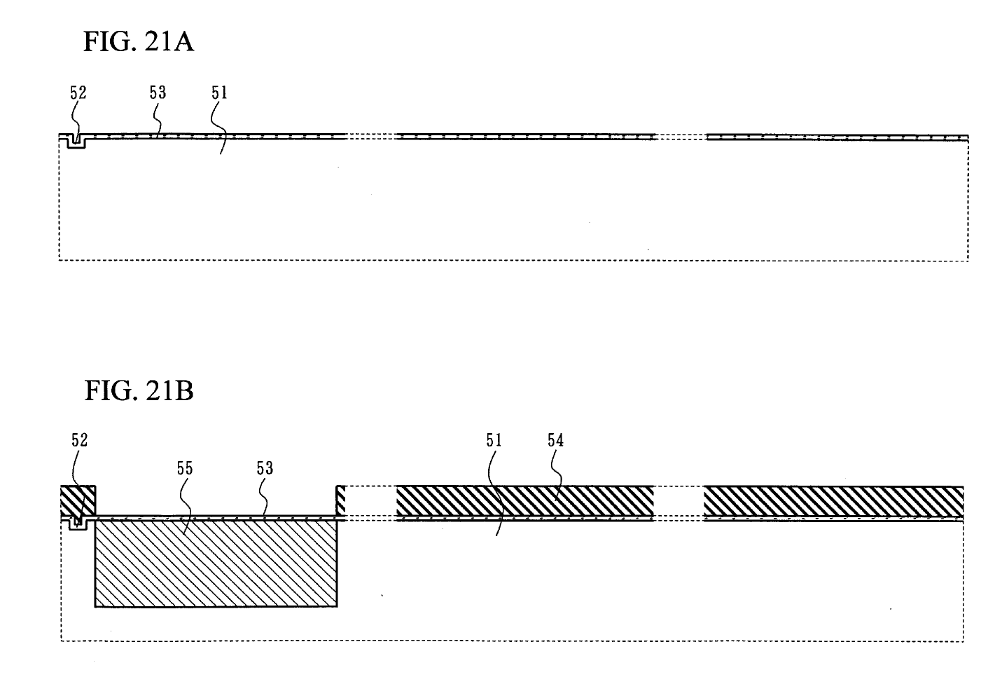

Next, referring to FIGS. 21A to 33V, the process steps of manufacturing the semiconductor integrated circuit device in Embodiment 6 of the present invention will be described. First, as illustrated in FIG. 21A, a mark 52 for mask alignment is formed outside the product formation region of a silicon substrate 51. Then, a SiO₂ film 53 having a thickness of 0.5 nm is formed over the entire surface of the silicon substrate 51 to protect the surface thereof.

Next, as illustrated in FIG. 21B, a photoresist mask 54 having an opening corresponding to an NMOS formation region is formed. Then, to form a deep p-type well region 55, B is ion-implanted from four directions at a dose of 7.5×10¹² cm⁻² with an acceleration energy of 150 keV. Note that the total dose is 3×10¹³ cm⁻².

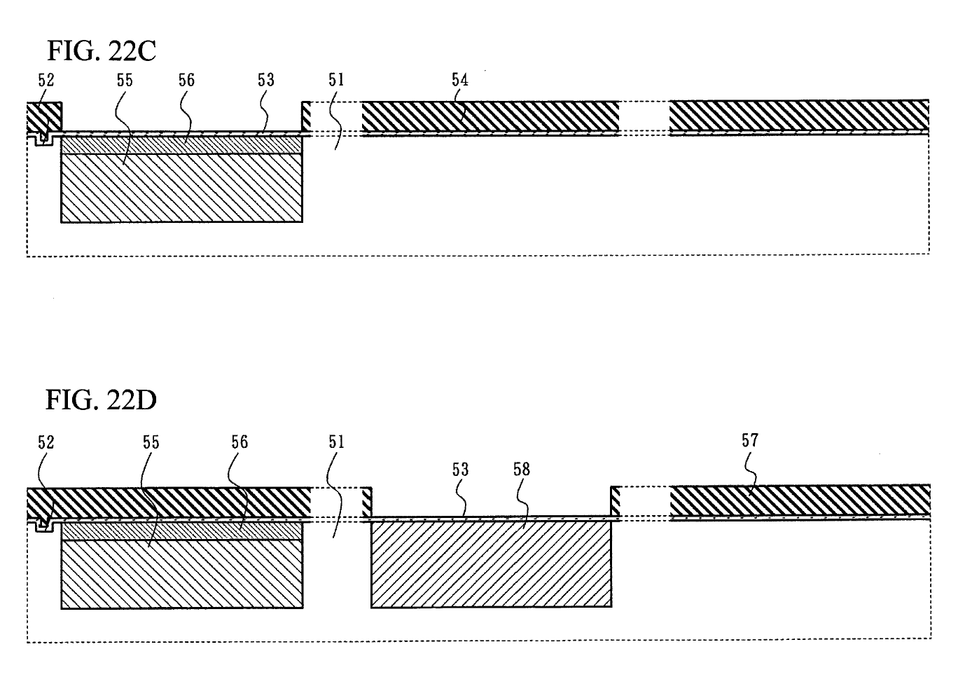

Subsequently, as illustrated in FIG. 22C, Ge is ion-implanted at a dose of 5×10¹⁴ cm⁻² with an acceleration energy of 30 keV and C is ion-implanted at a dose of 5×10¹⁴ cm⁻² with an acceleration energy of 5 keV. Note that Ge generates amorphous regions in Si substrate, C is more likely to be set at lattice position and C positioned at lattice position help to retard B diffusion. Then, to form a high-concentration screen layer 56 immediately under a channel region, B is ion-implanted at 0.9×10¹³ cm⁻² with an acceleration energy of 20 keV and at 1.0×10¹³ cm⁻² with an acceleration energy of 10 keV, while BF₂ is ion-implanted at 1.0×10¹³ cm⁻² with an acceleration energy of 10 keV.

Next, the photoresist mask 54 is removed. Then, the SiO₂ film 53 having a thickness of 3 nm is newly formed over the entire surface of the silicon substrate 51 to protect the surface thereof by an ISSG (in-situ steam generation) process performed at 810° C. for 20 seconds. Thereafter, as illustrated in FIG. 22D, a new photoresist mask 57 having an opening corresponding to a PMOS formation region is provided, and P is ion-implanted from four directions at a concentration of 7.5×10¹² cm⁻² with an acceleration energy of 360 keV to form a deep n-type well region 58.

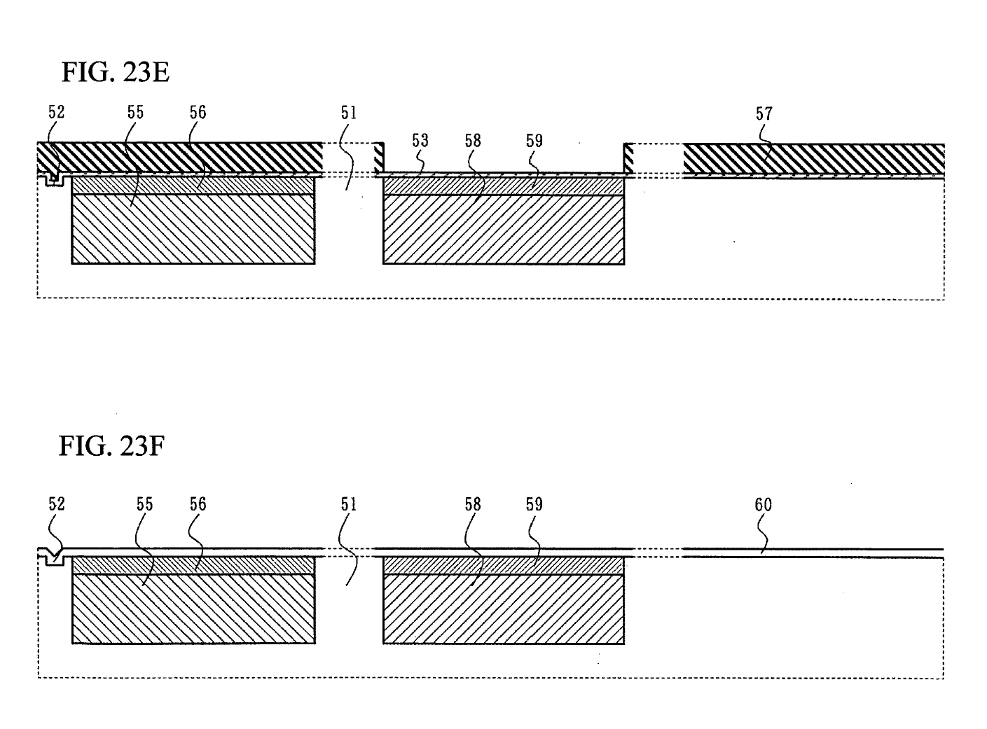

Subsequently, as illustrated in FIG. 23E, Sb is ion-implanted at 0.9×10¹³ cm⁻² with an acceleration energy of 130 keV, at 0.9×10¹³ cm⁻² with an acceleration energy of 80 keV, and at 1.5×10¹³ cm⁻² with an acceleration energy of 20 keV to form a high-concentration screen layer 59 immediately under the channel.

Next, the photoresist mask 57 is removed. Thereafter, annealing treatment is performed at 600° C. for 150 seconds to cause recrystallization, and then rapid thermal annealing is performed at 1000° C. for 0 seconds (i.e., several microseconds) to activate each of the implanted ions. Then, as illustrated in FIG. 23F, the SiO₂ film 53 is removed, and the entire surface is oxidized to grow a SiO₂ film of 3 nm by an ISSG (in-situ steam generation) process performed at 810° C. for 20 seconds, which is then removed. By doing so, knock-on oxygen implanted in the surface of the silicon substrate can be removed. Then, a non-doped silicon layer 60 having a thickness of 25 nm is epitaxially grown. The silicon layer 60 serves as the channel region.

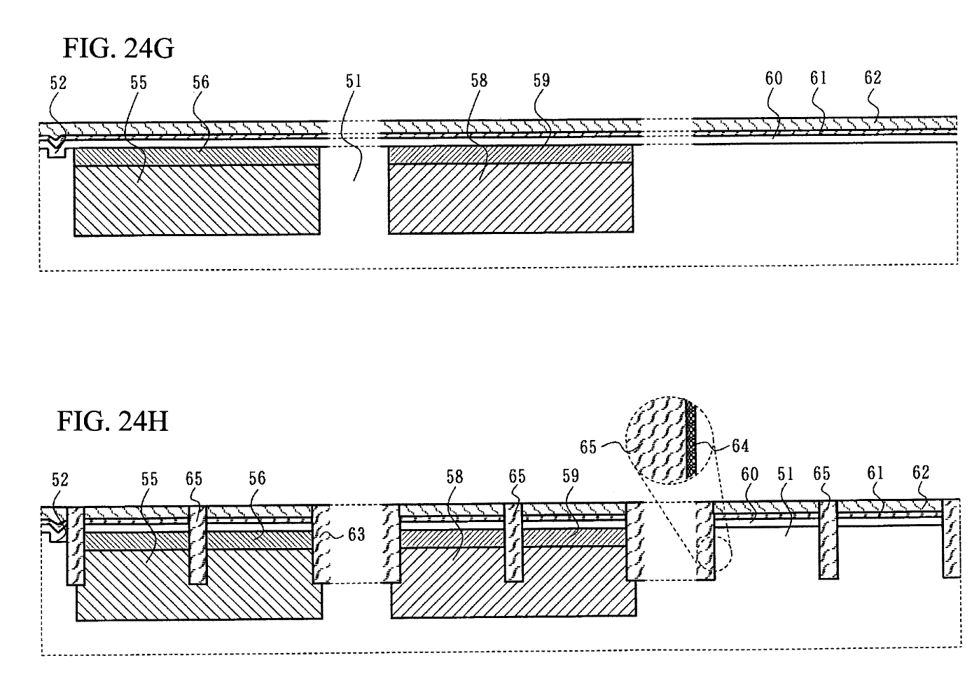

Next, as illustrated in FIG. 24G, by an ISSG (in-situ steam generation) process performed at 810° C. for 20 seconds, a SiO₂ film 61 having a thickness of 3 nm is formed on the surface of the silicon layer 60. Then, by a low pressure CVD process performed at 775° C. for 60 minutes, a SiN film 62 having a thickness of 90 nm is formed.

Next, as illustrated in FIG. 24H, an isolation trench 63 for STI (shallow trench isolation) is formed. Thereafter, by the ISSG process performed again at 810° C. for 20 seconds, a liner oxide film 64 is formed on the surface of the isolation trench 63. Then, using a HDP (high density plasma)-CVD method, over the entire surface, a SiO₂ film 65 is grown at 450° C. to completely fill the isolation trench 63. Then, using a CMP (chemical mechanical polishing) method using the SiN film 62 as a stopper, the surplus SiO₂ film 65 is removed by polishing.

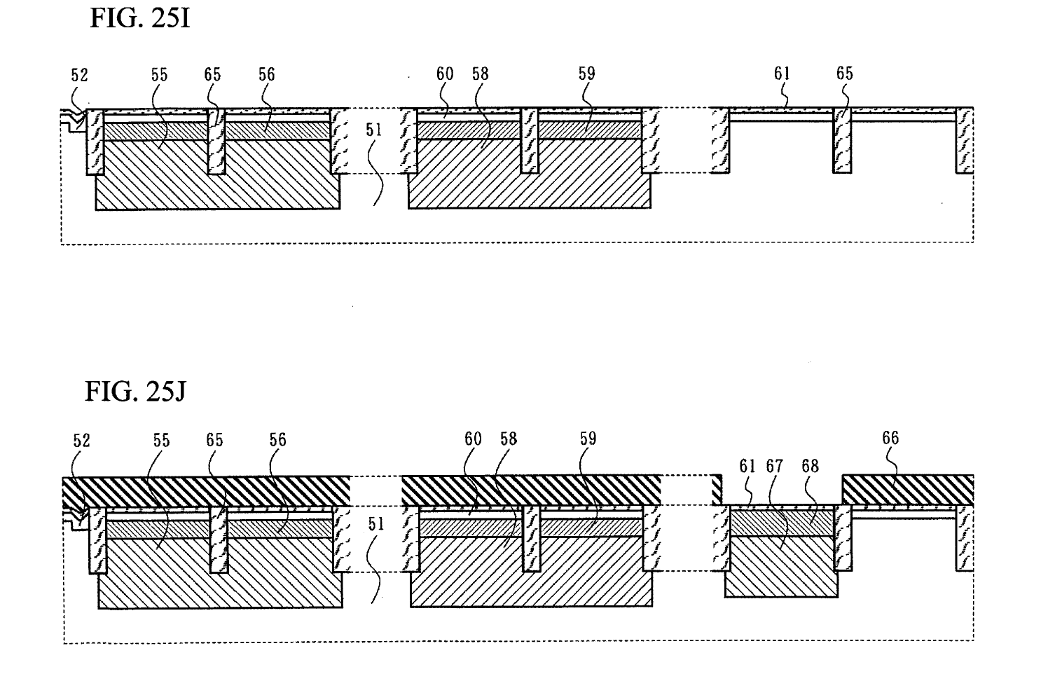

Next, as illustrated in FIG. 25I, using a HF solution, the surface of the SiO₂ film 65 corresponding to the thickness of 50 nm is removed. Thereafter, the SiN film 62 is removed using a phosphoric acid.

Next, as illustrated in FIG. 25J, a photoresist mask 66 having an opening corresponding to a high-voltage-operation NMOS formation region is provided, and B is ion-implanted from four directions at a dose of 7.5×10¹² cm⁻² with an acceleration energy of 150 keV to form a deep p-type well region 67. Subsequently, B is implanted at a dose of 5×10¹² cm⁻² with an acceleration energy of 2 keV to form a channel doped region 68.

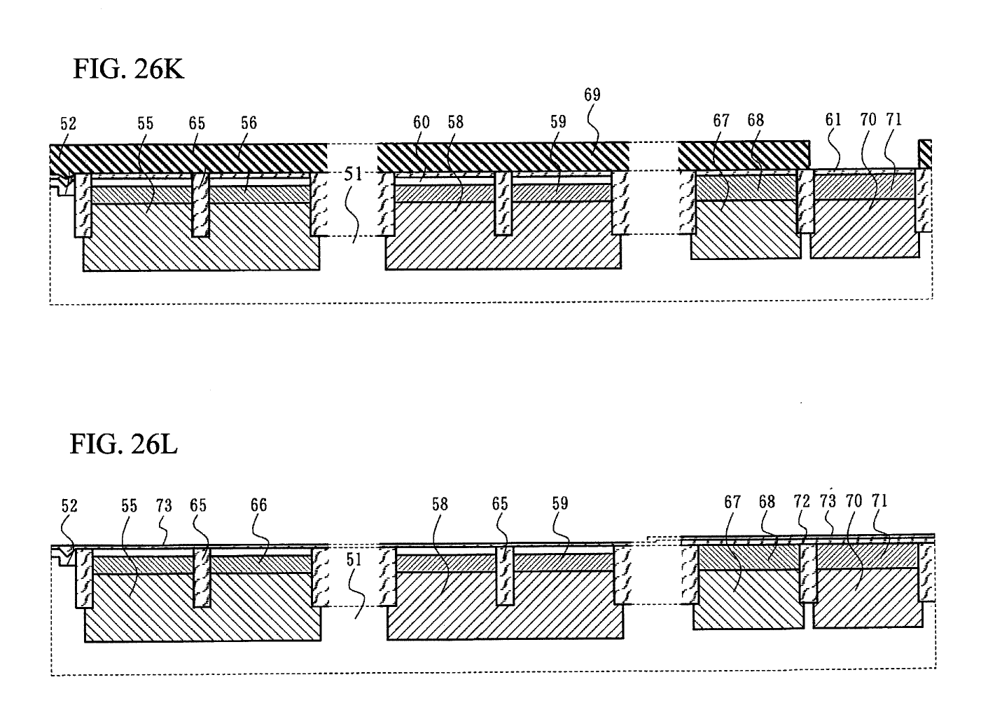

Next, as illustrated in FIG. 26K, the photoresist mask 66 is removed, and then a photoresist mask 69 having an opening corresponding to a high-voltage-operation PMOS formation region is newly provided. Then, using the photoresist mask 69 as a mask, P is ion-implanted from four directions at a dose of 7.5×10¹² cm⁻² with an acceleration energy of 360 keV to form a deep n-type well region 70. Subsequently, P is implanted at a dose of 5×10¹² cm⁻² with an acceleration energy of 2 keV to form a channel doped region 71.

Next, as illustrated in FIG. 26L, the photoresist mask 69 is removed. Thereafter, the SiO₂ film 61 is removed, and oxidation treatment is performed at 750° C. for 52 minutes to form a gate oxide film 72 having a thickness of 7 nm. Then, the gate oxide film 72 is selectively removed from the surface of a low-voltage-operation MOS formation region. Thereafter, by an ISSG process performed at 810° C. for 8 seconds, a SiO₂ film having a thickness of 2 nm is formed to be used as a gate oxide film 73.

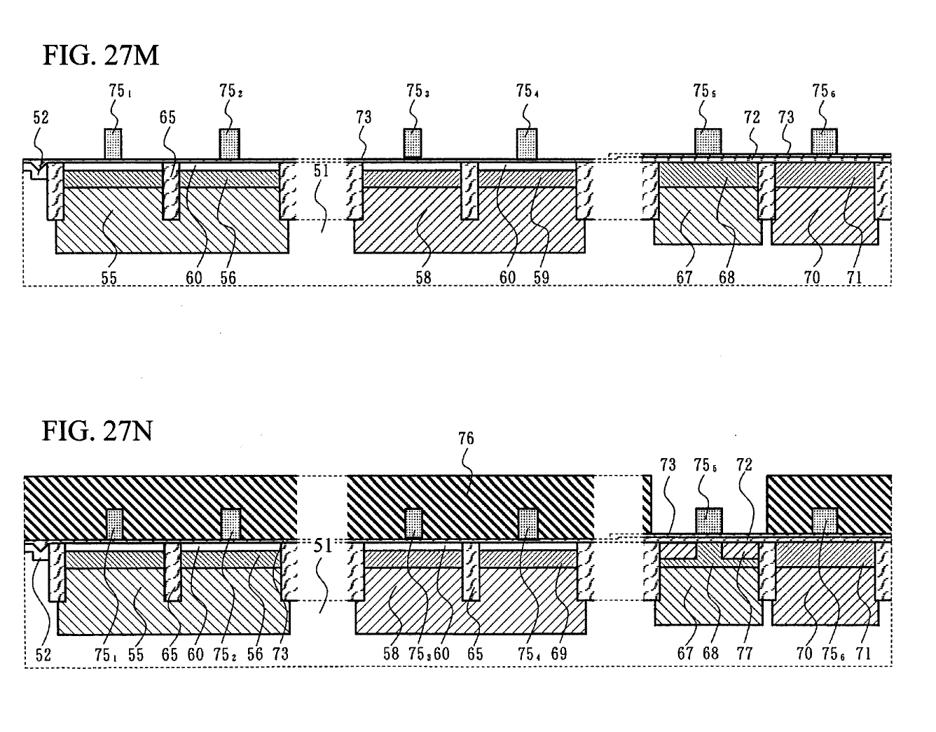

Next, as illustrated in FIG. 27M, by a low pressure CVD method performed at 605° C., a non-doped polysilicon layer having a thickness of 100 nm is formed and then patterned to form gate electrodes 75₁ to 75₆. Here, the gate length of each of the gate electrodes 75₁ and 75₃ in a low-voltage-operation high-speed MOS formation region is set to 45 nm, and the gate length of each of the gate electrodes 75₂ and 75₄ in a low-voltage-operation low-leak-current MOS formation region is set to 55 nm. On the other hand, the gate length of each of the gate electrodes 75₅ and 75₆ in the high-voltage-operation MOS formation region is set to 340 nm.

Next, as illustrated FIG. 27N, a photoresist mask 76 having an opening corresponding to the high-voltage-operation NMOS formation region is provided, and P is ion-implanted at a dose of 2×10¹³ cm⁻² with an acceleration energy of 35 keV to form n-type LDD regions 77.

Next, as illustrated in FIG. 280, the photoresist mask 76 is removed, and then a photoresist mask 78 having respective openings corresponding to the high-voltage-operation PMOS formation region and a low-voltage-operation low-leakage-current PMOS formation region is provided. Then, using the photoresist mask 78 as a mask, B is ion-implanted at a dose of 2×10¹⁴ cm⁻² with an acceleration energy of 0.3 keV to simultaneously form p-type LDD regions 79 and 80.

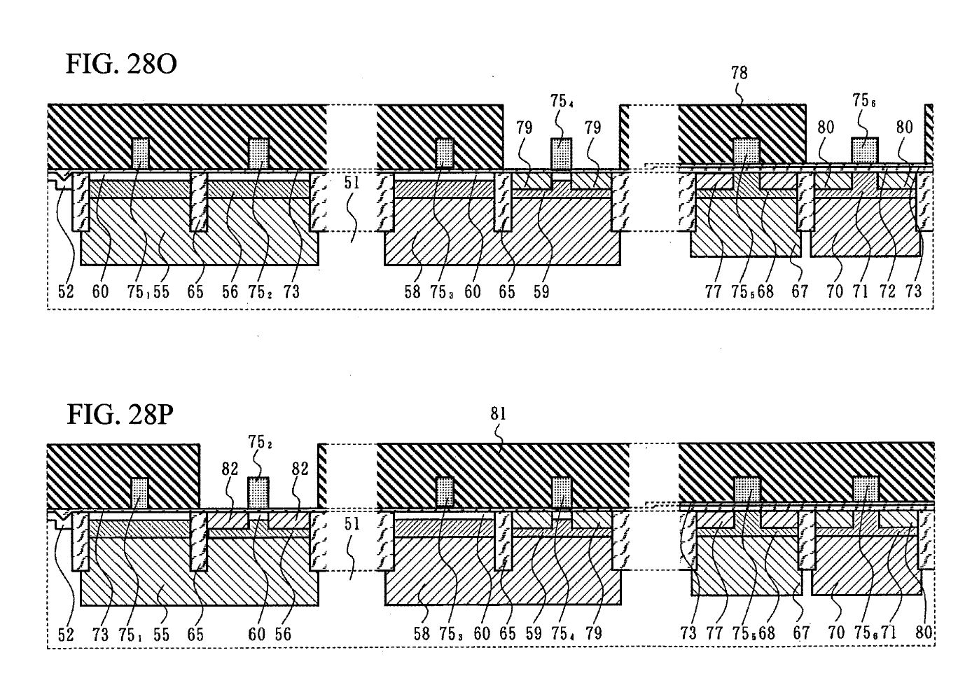

Next, as illustrated in FIG. 28P, the photoresist mask 78 is removed, and then a photoresist mask 81 having an opening corresponding to a low-voltage-operation low-leakage-current NMOS formation region is provided. Then, using the photoresist mask 81 as a mask, As is ion-implanted at a dose of 4×10¹⁴ cm⁻² with an acceleration energy of 1 keV to form n-type extension regions 82.

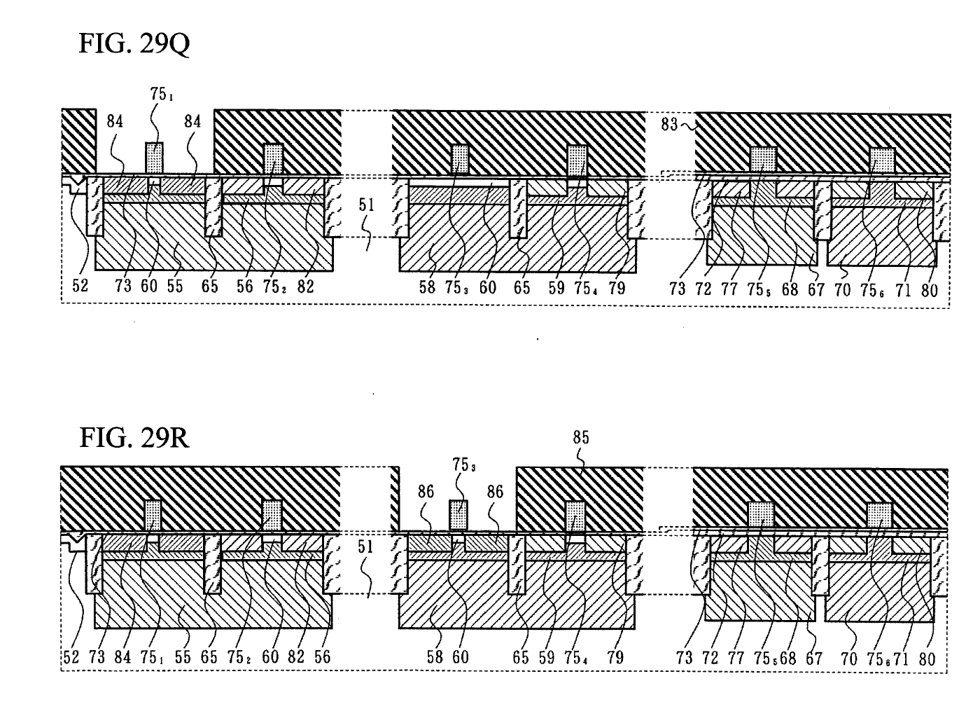

Next, as illustrated in FIG. 29Q, the photoresist mask 81 is removed, and then, a photoresist mask 83 having an opening corresponding to a low-voltage-operation high-speed NMOS formation region is provided. Then, using the photoresist mask 83 as a mask, As is ion-implanted at a dose of 8×10¹⁴ cm⁻² with an acceleration energy of 1 keV to form n-type extension regions 84.

Next, as illustrated in FIG. 29R, the photoresist mask 83 is removed, and then a photoresist mask 85 having an opening corresponding to a low-voltage-operation high-speed PMOS formation region is provided. Then, using the photoresist mask 85 as a mask, B is ion-implanted at a dose of 3.6×10¹⁴ cm⁻² with an acceleration energy of 0.3 keV to form p-type extension regions 86.

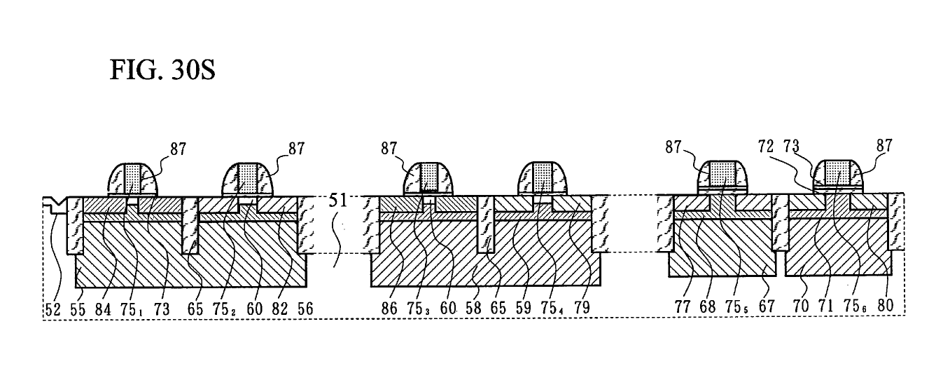

Next, as illustrated in FIG. 30S, the photoresist mask 85 is removed. Thereafter, by a CVD method, a SiO₂ film having a thickness of 80 nm is formed over the entire surface at 520° C. and then etched by reactive ion etching to form sidewalls 87.

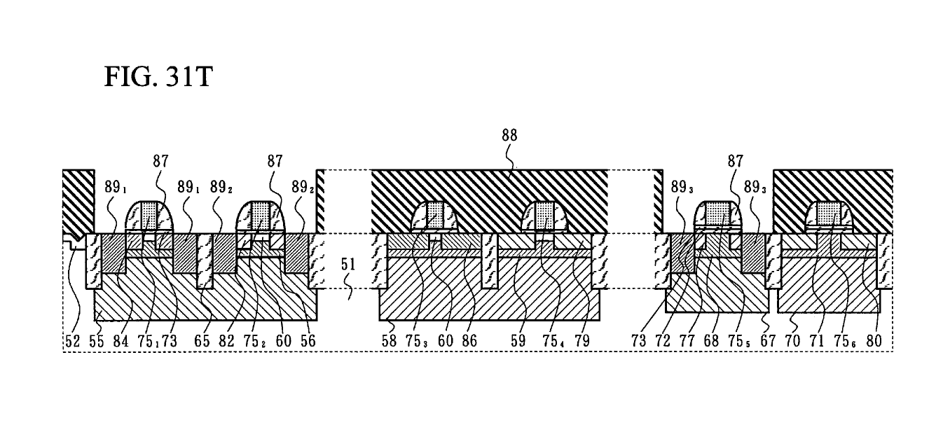

Next, as illustrated in FIG. 31T, a photoresist mask 88 having an opening corresponding to the NMOS formation region is formed, and P is ion-implanted at a dose of 1.2×10¹⁶ cm⁻² with an acceleration energy of 8 keV to form n-type source/drain regions 89₁ to 89₃. At this time, gate doping is simultaneously performed on the gate electrodes 75₃, 75₄, and 75₆.

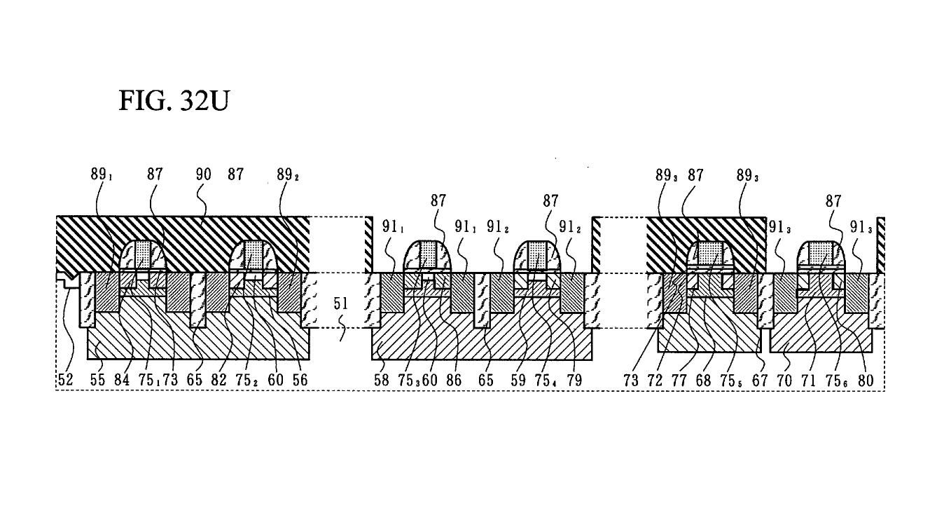

Next, as illustrated in FIG. 32U, the photoresist mask 88 is removed, and then a photoresist mask 90 having an opening corresponding to the PMOS formation region is formed. Using the photoresist mask 90 as a mask, B is ion-implanted at a dose of 6×10¹⁵ cm⁻² with an acceleration energy of 4 keV to form p-type source/drain regions 91₁ to 91₃. At this time, gate doping is simultaneously performed on the gate electrodes 75₁, 75₂, and 75₅.

Then, the photoresist mask 90 is removed. Thereafter, rapid thermal annealing is performed at 1025° C. for 0 seconds (several microseconds) to activate the implanted ions and also diffuse the impurities in the gate electrodes 75₁ to 75₆. Note that the rapid thermal annealing performed at 1025° C. for 0 seconds is sufficient to diffuse the impurities to the interfaces between the lowermost portions of the gate electrodes 75₁, 75₂, and 75₅ and the gate oxide films. On the other hand, in the channel region of the NMOS, the implanted C suppresses diffusion of B while, in the channel region of the PMOS, slow diffusion of Sb holds a steep impurity distribution.

Thereafter, a Co sputtering step, a heat treatment step for silicidation, the step of removing unreacted Co, and the step of forming a SiN stopper film having a thickness of 50 nm are successively performed, though the illustration thereof is omitted.

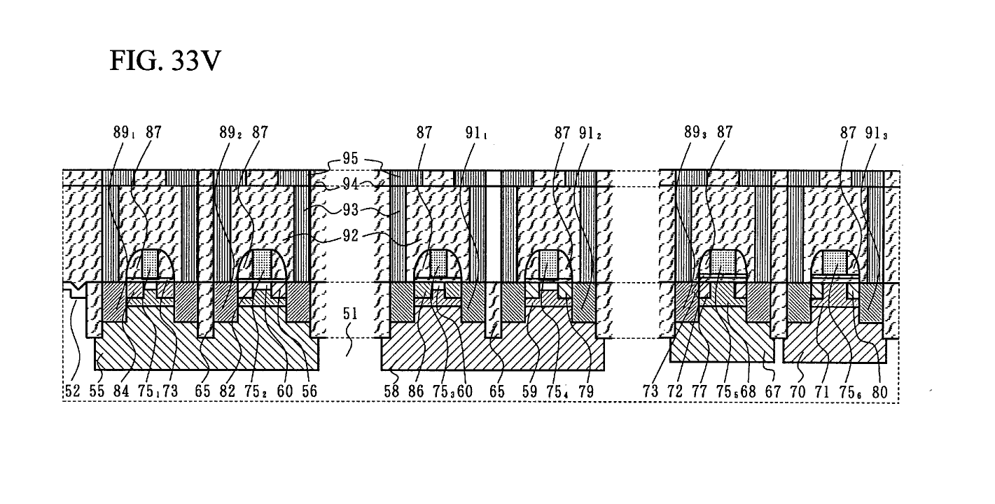

Next, as illustrated in FIG. 33V, an interlayer insulating film 92 made of SiO₂ and having a thickness of 500 nm is formed by a HDP-CVD method and planarized by a CMP method. In the interlayer insulating film 92, via holes reaching the source/drain regions are formed, and plugs 93 are formed therein.

Next, a SiN stopper film (illustration thereof is omitted) and a second interlayer insulating film 94 are formed, and wire trenches exposing the plugs 93 are formed therein. In the wire trenches, Cu is embedded via a barrier metal (illustration thereof is omitted) and polished by a CMP method to form embedded wires 95. Thereafter, the steps of forming an interlayer insulating film, forming plugs, forming an interlayer insulating film, and forming embedded wires are performed in accordance with the needed number of multilayer interconnects, though illustration thereof is omitted. In this manner, the basic structure of the semiconductor integrated circuit device is completed.

Thus, in Embodiment 6 of the present invention, high-voltage-driven portions are formed of the conventional macro cells, while low-voltage-driven portions are formed of the macro cells of the present invention. In each of the low-voltage-driven portions, Vₜₕ is controlled using the channel length and the impurity concentrations of the LDD regions to achieve low I_{off}. In addition, the LDDs of the high-voltage-operation PMOS and the LDDs of the low-voltage-operation low-L_{off} PMOS are formed in the same common step to achieve each of the omission of a step and a reduction in the junction leakage in the high-voltage-operation PMOS.

### Embodiment 7

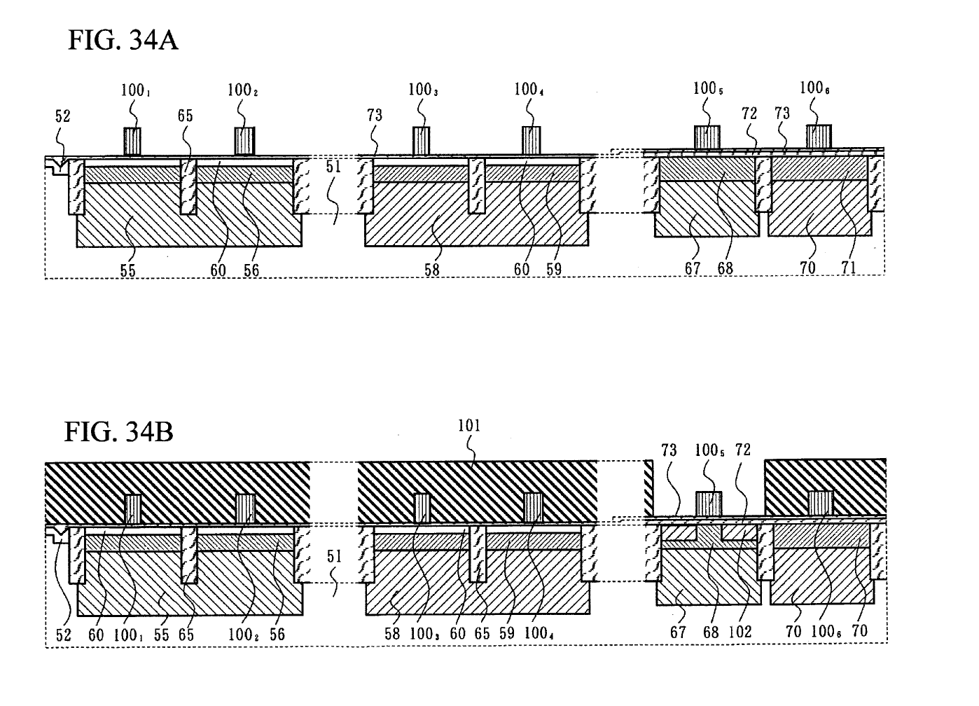

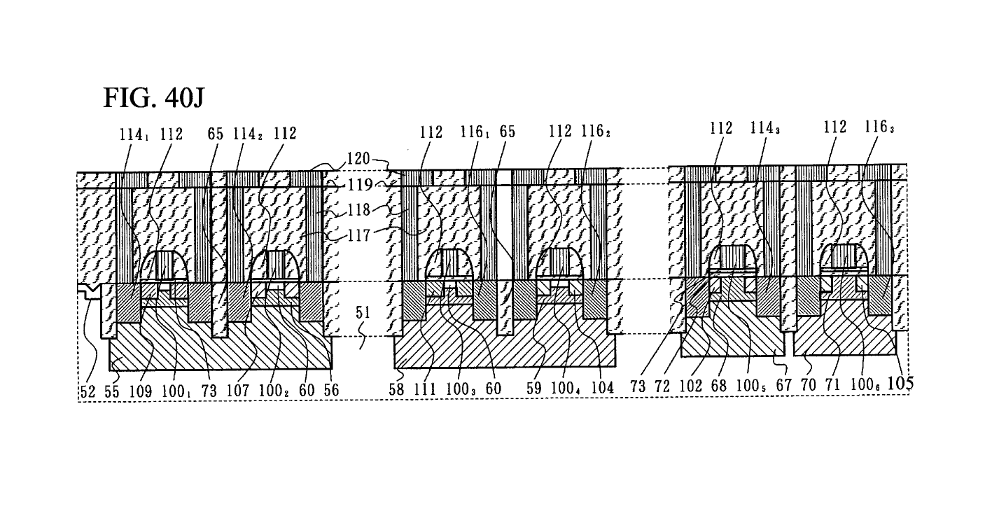

Next, referring to FIGS. 34A to 40, a semiconductor integrated circuit device of Embodiment 7 of the present invention will be described. However, since the overall configuration thereof is the same as in Embodiment 6 described above, manufacturing process steps will be described. Note that Embodiment 7 of the present invention uses TiN, instead of polysilicon, for each of gate electrodes. Otherwise, the basic steps are the same as in each of the embodiments described above.

First, as illustrated in FIG. 34A, by exactly the same steps as in FIGS. 21A to 26L described above, six type of well regions are formed. Then, a TiN film having a thickness of 100 nm is formed by a sputtering method and then patterned to form gate electrodes 100₁ to 100₆. Here, the gate length of each of the gate electrodes 100₁ and 100₃ in the low-voltage-operation high-speed MOS formation region is set to 45 nm, while the gate length of each of the gate electrodes 100₂ and 100₄ in the low-voltage-operation low-leakage-current MOS formation region is set to 55 nm. On the other hand, the gate length of each of the gate electrodes 100₅ and 100₆ in the high-voltage-operation MOS formation region is set to 340 nm. Note that the composition ratio of TiN is Ti:N=1:1.

Next, as illustrated in FIG. 34B, a photoresist mask 101 having an opening corresponding to the high-voltage-operation NMOS formation region is provided, and P is ion-implanted at a dose of 2×10¹³ cm⁻² with an acceleration energy of 35 keV to form n-type LDD regions 102.

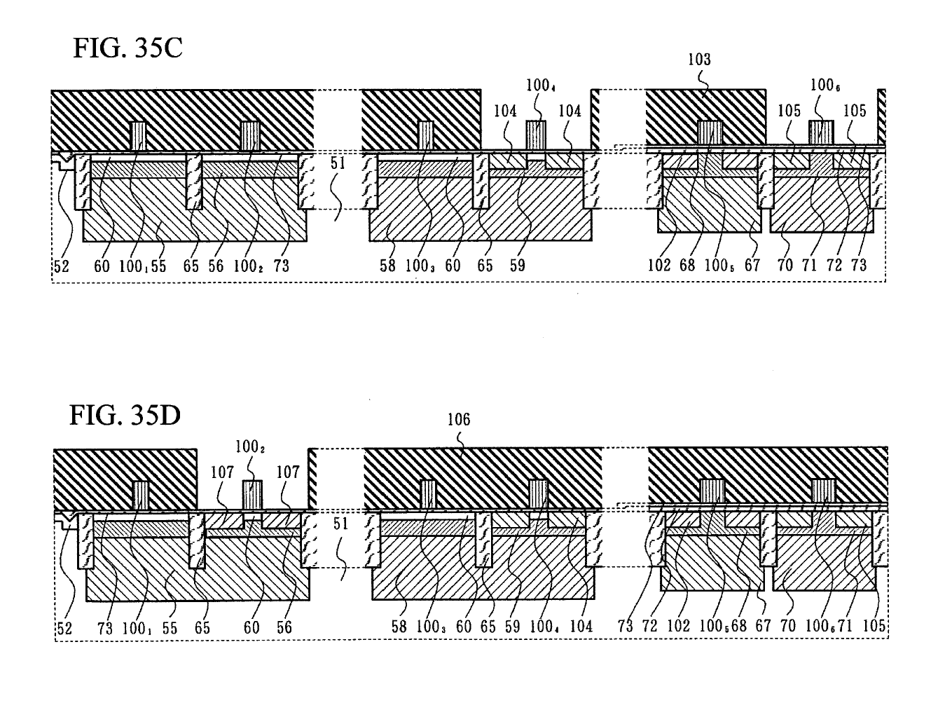

Next, as illustrated in FIG. 35C, the photoresist mask 101 is removed, and then a photoresist mask 103 having respective openings corresponding to the high-voltage-operation PMOS formation region and the low-voltage-operation low-leakage-current PMOS formation region is provided. Then, using the photoresist mask 103 as a mask, B is ion-implanted at a dose of 2×10¹⁴ cm⁻² with an acceleration energy of 0.3 keV to simultaneously form p-type LDD regions 104 and 105.

Next, as illustrated in FIG. 35D, the photoresist mask 103 is removed, and then a photoresist mask 106 having an opening corresponding to the low-voltage-operation low-leakage-current NMOS formation region is provided. Then, using the photoresist mask 106 as a mask, As is ion-implanted at a dose of 4×10¹⁴ cm⁻² with an acceleration energy of 1 keV to form n-type extension regions 107.

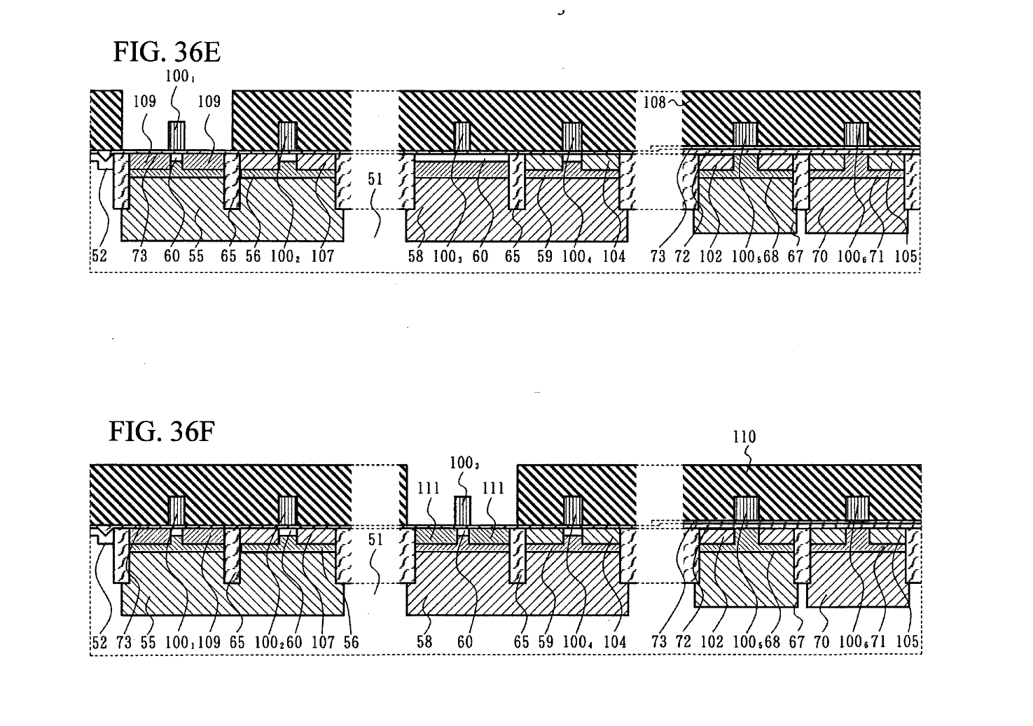

Next, as illustrated in FIG. 36E, the photoresist mask 106 is removed, and then a photoresist mask 108 having an opening corresponding to the low-voltage-operation high-speed NMOS formation region is provided. Then, using the photoresist mask 108 as a mask, As is ion-implanted at a dose of 8×10¹⁴ cm⁻² with an acceleration energy of 1 keV to form n-type extension regions 109.

Next, as illustrated in FIG. 36F, the photoresist mask 108 is removed, and then a photoresist mask 110 having an opening corresponding to the low-voltage-operation high-speed PMOS formation region is provided. Then, using the photoresist mask 110 as a mask, B is ion-implanted at a dose of 3.6×10¹⁴ cm⁻² with an acceleration energy of 0.3 keV to form p-type extension regions 111.

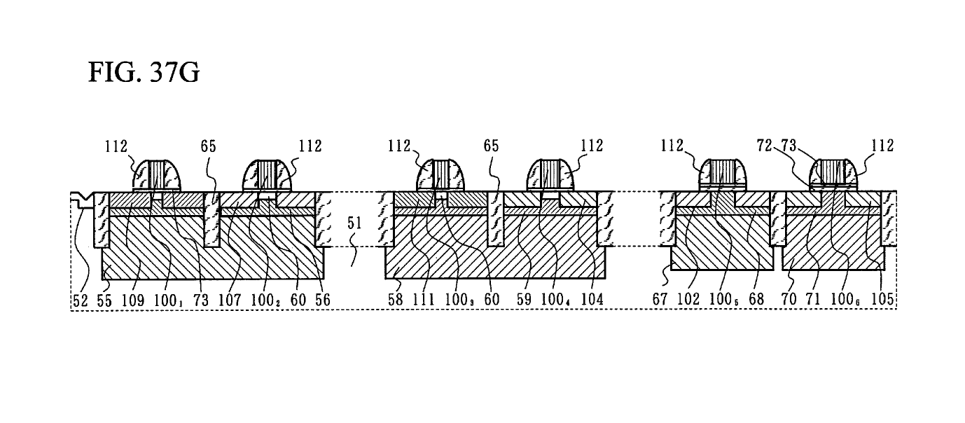

Next, as illustrated in FIG. 37G, the photoresist mask 110 is removed. Thereafter, by a CVD method, a SiO₂ film having a thickness of 80 nm is formed over the entire surface at 520° C. and then etched by reactive ion etching to form sidewalls 112.

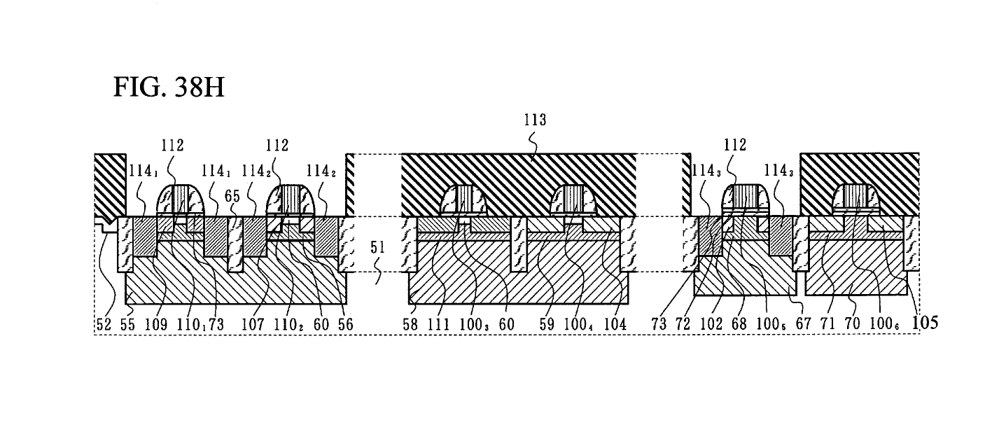

Next, as illustrated in FIG. 38H, a photoresist mask 113 having an opening corresponding to the NMOS formation region is formed, and P is ion-implanted at a dose of 4×10¹⁵ cm⁻² with an acceleration energy of 8 keV to form n-type source/drain regions 114₁ to 114₃.

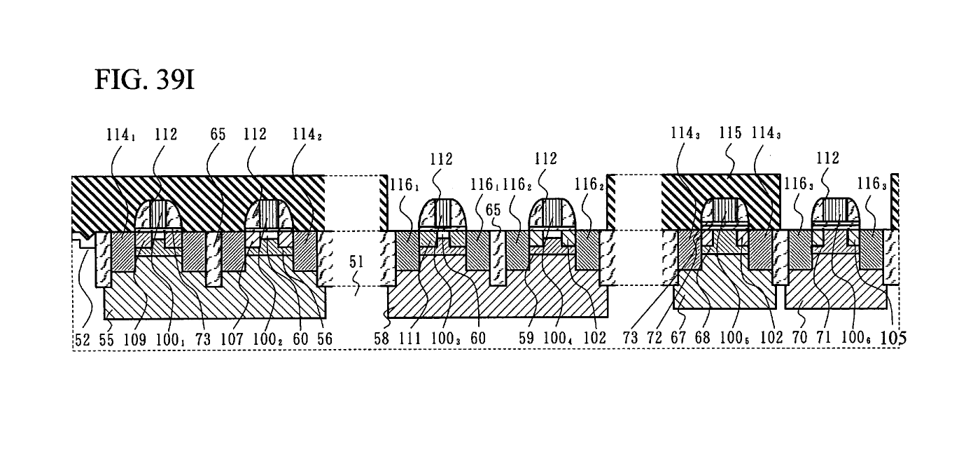

Next, as illustrated in FIG. 39I, the photoresist mask 113 is removed, and then a photoresist mask 115 having an opening corresponding to the PMOS formation region is formed. Using the photoresist mask 115 as a mask, B is ion-implanted at a dose of 4×10¹⁵ cm⁻² with an acceleration energy of 4 keV to form p-type source/drain regions 116₁ to 116₃.

Next, the photoresist mask 115 is removed. Thereafter, rapid thermal annealing is performed at 950° C. for 0 seconds (several microseconds) to activate the implanted ions.

Thereafter, a Co sputtering step, a heat treatment step for silicidation, the step of removing unreacted Co, and the step of forming a SiN stopper film are successively performed, though the illustration thereof is omitted.

Then, as illustrated in FIG. 403, an interlayer insulating film 117 made of SiO₂ and having a thickness of 500 nm is formed by a HDP-CVD method and then planarized by a CMP method. In the interlayer insulating film 117, via holes reaching the source/drain regions are formed, and plugs 118 are formed therein.

Next, a SiN stopper film (illustration thereof is omitted) and a second interlayer insulating film 119 are formed to form wire trenches exposing the plugs 118. In the wire trenches, Cu is embedded via a barrier metal (illustration thereof is omitted) and polished by a CMP method to form embedded wires 120. Thereafter, the steps of forming an interlayer insulating film, forming plugs, forming an interlayer insulating film, and forming embedded wires are performed in accordance with the needed number of multilayer interconnects, though the illustration thereof is omitted. In this manner, the basic structure of the semiconductor integrated circuit device of Embodiment 7 of the present invention is completed.

In Example 7 of the present invention, TiN is used for each of the gate electrodes. As a result, the work function is controlled using an N concentration to be able to be set at a value in the vicinity of the middle of the band gap of Si. By doing so, compared to the case where n-type polysilicon is used for an NMOS and p-type polysilicon is used for a PMOS, the channel impurity concentration needed to achieve the same threshold voltage Vₜₕ can be reduced. Consequently, a junction leakage can be reduced.

Since TiN is inherently a metal, there is no need to diffuse an impurity in the gate electrode, unlike in the case where a polysilicon gate electrode is used. This can reduce a heat treatment temperature and suppress a reduction in the threshold voltage Vₜₕ due to the short channel effect. In terms of this also, the channel impurity concentration can be reduced to allow a reduction in junction leakage.

In addition, since TiN need not be doped with an impurity, the impurity concentration can be reduced when the source/drain regions are formed. Here, for the NMOS, the impurity concentration was reduced to ⅓ of the impurity concentration when the polysilicon gate electrode was used and, for the PMOS, the impurity concentration was reduced to ⅔ of the impurity concentration when the polysilicon gate electrode was used.

Note that, when polysilicon is used for each of the gate electrodes and the doping of polysilicon and the source/drain formation are simultaneously performed, to suppress the depletion of the polysilicon gate electrode, the impurity concentration needs to be increased to a significantly high level. As a result, the threshold voltage Vₜₕ decreases considerably due to the short channel effect to cause the need to increase the channel impurity concentration, resulting in a greater junction leakage. The problem is solved by performing the doping of polysilicon and the formation of the source/drain regions, but the number of process steps increases.

Here, to the embodiments of the present invention including Embodiments 1 to 7, the following notes are added.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor integrated circuit device, comprising:
a first transistor; and
a second transistor having a threshold voltage higher than that of the first transistor, and a leakage current at a lower level than that of the first transistor, wherein
the first transistor includes a non-doped first channel region, and a first screen region in contact with and immediately under the first channel region,
the second transistor includes a non-doped second channel region, and a second screen region in contact with and immediately under the second channel region,
a first impurity concentration distribution in each of the first channel region and the first screen region is equal to a second impurity concentration distribution in each of the second channel region and the second screen region, and
a first effective channel length of the first transistor is shorter than a second effective channel length of the second transistor.

2. The semiconductor integrated circuit device according to claim 1, wherein a first gate length of the first transistor is shorter than a second gate length of the second transistor.

3. The semiconductor integrated circuit device according to claim 1, wherein
a first gate length is equal to a second gate length, and
a second impurity concentration in each of a second source region and a second drain region each in contact with the second channel region is lower than a first impurity concentration in each of a first source region and a first drain region each in contact with the first channel region.

4. The semiconductor integrated circuit device according to claim 3, wherein a gradient of the second impurity concentration in each of the second source region and the second drain region is less steep than a gradient of the first impurity concentration in each of the first source region and the first drain region.

5. The semiconductor integrated circuit device according to claim 1, wherein a body bias is applied to each of the first transistor and the second transistor.

6. The semiconductor integrated circuit device according to claim 1, further comprising:
a third transistor having a third effective channel length greater than the second effective channel length; and
a third circuit having a threshold voltage higher than that of a second circuit, and a leakage current at a lower level than that of the second circuit.

7. The semiconductor integrated circuit device according to claim 6, wherein
the third transistor includes a third channel region, and a third screen region in contact with and immediately under the third channel region,
a third impurity concentration distribution in each of the third channel region and the third screen region is equal to each of the first impurity concentration distribution and the second impurity concentration distribution,
the second gate length is greater than the first gate length,
the second impurity concentration in each of the second source region and the second drain region is equal to the first impurity concentration in each of the first source region and the first drain region,
a third gate length of the third transistor is equal to or greater than the second gate length, and
a third impurity concentration in each of a third source region and a third drain region of the third transistor is lower than the second impurity concentration.

8. The semiconductor integrated circuit device according to claim 6, wherein
a third impurity in each of the third source region and the third drain region is the same as a second impurity in each of the second source region and the second drain region, and
the third transistor is a transistor to be driven at a voltage higher than a voltage at which the second transistor is driven.

9. The semiconductor integrated circuit device according to claim 1, wherein a gate electrode of each of the first, second, and third transistors is a metal gate.

10. A semiconductor integrated circuit device, wherein
a first circuit including a first transistor and a second circuit including a second transistor and having a threshold voltage higher than that of the first circuit, and a leakage current at a lower level than that of the first circuit form a circuit macro used commonly to a first product group and a second product group,
when the circuit macro is used for the first product group, a first threshold voltage of the first transistor is adjusted to be lower than a second threshold voltage of the second transistor by using a difference between respective impurity concentrations in a first channel region of the first transistor and in a second channel region of the second transistor, and
when the circuit macro is used for the second product group, the first threshold voltage is adjusted to be lower than the second threshold voltage by using a difference between a first gate length of the first transistor and a second gate length of the second transistor, and a minimum gate length in the first and second transistors in the second product group is adjusted to be shorter than a minimum gate length in the first and second transistors in the first product group.

11. The semiconductor integrated circuit device according to claim 10, wherein
each of the first product group and the second product group includes a third transistor having an effective channel length greater than a second effective channel length of the second transistor, and further includes a third circuit having an operation speed lower than that of the second circuit, and a leakage current at a lower level than that of the second circuit,
when the circuit macro is used for the first product group, a third threshold voltage of the third transistor is adjusted to be higher than the second threshold voltage of the second transistor by using an impurity concentration in a channel region, and
when the circuit macro is used for the second product group, the third threshold voltage is adjusted to be higher than the second threshold voltage by using a gate length.

12. A method of manufacturing a semiconductor integrated circuit device, comprising:
forming a first well region of a first conductivity type in a semiconductor substrate, while forming a first screen layer having an impurity concentration higher than that of the first well region in a surface of the first well region;
forming a non-doped layer over the semiconductor substrate;
forming a first isolation region for dividing the first well region into a second well region of the first conductivity type and a third well region of the first conductivity type;
forming a first gate electrode over the second well region via a gate insulating film, while forming a second gate electrode having a gate length greater than that of the first gate electrode over the third well region via a gate insulating film;
introducing an impurity of a second conductivity type opposite to the first conductivity type into the second well region by using the first gate electrode as a mask to form a first source region and a first drain region; and
introducing an impurity of the second conductivity type into the third well region by using the second gate electrode as a mask to form a second source region and a second drain region each having an impurity concentration lower than that of each of the first source region and the first drain region.

13. The method of manufacturing the semiconductor integrated circuit device according to claim 12, further comprising:
forming a fourth well region having the second conductivity type in the semiconductor substrate, while forming a second screen layer having an impurity concentration higher than that of the fourth well region in a surface of the fourth well region;
forming a second isolation region for dividing the fourth well region into a fifth well region and a sixth well region;
forming a third gate electrode of the same gate length as that of the first gate electrode over the fifth well region via a gate insulating film, while forming a fourth gate electrode having the same gate length as that of the second gate electrode over the sixth well region via a gate insulating film;
introducing a first impurity of the first conductivity type into the fifth well region by using the third gate electrode as a mask to form a third source region and a third drain region each being of the first conductivity type; and
introducing a second impurity of the first conductivity type into the sixth well region by using the fourth gate electrode as a mask to form a fourth source region and a fourth drain region each being of the first conductivity type and having an impurity concentration lower than that of each of the third source region and the third drain region.

14. The method of manufacturing the semiconductor integrated circuit device according to claim 13, further comprising:
forming, after the non-doped layer is formed, a seventh well region of the first conductivity type and an eighth well region of the second conductivity type in a region where the first well region and the fourth well region are not formed;
forming a fifth gate electrode having a gate length equal to or greater than that of the second gate electrode over the seventh well region;
introducing a third impurity of the second conductivity type by using the fifth gate electrode as a mask to form a fifth source region and a fifth drain region;
forming a sixth gate electrode having a gate length equal to or greater than that of the fourth gate electrode over the eighth well region; and
introducing a fourth impurity of the first conductivity type by using the sixth gate electrode as a mask to form a sixth source region and a sixth drain region.

15. The method of manufacturing the semiconductor integrated circuit device according to claim 12, further comprising:
forming a high-concentration source region and a high-concentration drain region outside each of the source regions and each of the drain regions.

16. The method of manufacturing the semiconductor integrated circuit device according to claim 13, further comprising:
forming a high-concentration source region and a high-concentration drain region outside each of the source regions and each of the drain regions.

17. The method of manufacturing the semiconductor integrated circuit device according to claim 14, further comprising:
forming a high-concentration source region and a high-concentration drain region outside each of the source regions and each of the drain regions.

18. The method of manufacturing the semiconductor integrated circuit device according to claim 12, wherein
the first conductivity type is a p-type, and
the forming of the fourth source region and the fourth drain region and the forming of the sixth source region and the sixth drain region are implemented simultaneously.

19. The method of manufacturing the semiconductor integrated circuit device according to claim 12, wherein each of the gate electrodes is a TiN gate electrode.

20. The method of manufacturing the semiconductor integrated circuit device according to claim 13, wherein each of the gate electrodes is a TiN gate electrode.
